(19) United States
(12) Patent Application Publication
(10) Pub. No.: US 2025/0151271 A1
(43) Pub. Date: May 8, 2025

(54) SEMICONDUCTOR DEVICE AND MANUFACTURING METHOD OF THE SAME, AND ELECTRONIC SYSTEM INCLUDING SEMICONDUCTOR DEVICE

(71) Applicant: Samsung Electronics Co., Ltd., Suwon-si (KR)

(72) Inventors: Sehoon LEE, Suwon-si (KR); Bumkyu KANG, Suwon-si (KR); Sukkang SUNG, Suwon-si (KR); Younghwan SON, Suwon-si (KR)

(73) Assignee: Samsung Electronics Co., Ltd., Suwon-si (KR)

(21) Appl. No.: 18/675,463

(22) Filed: May 28, 2024

(30) Foreign Application Priority Data
Nov. 3, 2023 (KR) 10-2023-0151202

(51) Int. Cl. H10B 43/27; G11C 16/04; H01L 25/065; H10B 41/10; H10B 41/27; H10B 41/35; H10B 43/10; H10B 43/35; H10B 80/00

(52) U.S. Cl. CPC H10B 43/27; G11C 16/0483; H01L 25/0652; H10B 41/10; H10B 41/27; H10B 41/35; H10B 43/10; H10B 43/35; H10B 80/00; H01L 2225/06506

(57) ABSTRACT

A semiconductor device including a gate stacking structure, a plurality of channel structures, and a separation pattern. The plurality of channel structures including an adjacent channel structure including a first portion having a surface adjacent to the separation pattern and a separation surface spaced apart from the separation pattern. At least one of the gate dielectric layer or the channel layer is on the separation surface and the adjacent surface in the first portion of the adjacent channel structure.

### CROSS-REFERENCE TO RELATED APPLICATION

This application claims priority to and the benefit of Korean Patent Application No. 10-2023-0151202 filed in the Korean Intellectual Property Office on Nov. 3, 2023, the entire contents of which are incorporated herein by reference.

### BACKGROUND

### (a) Field

The present disclosure relates to a semiconductor device and a manufacturing method of the same, and an electronic system including a semiconductor device.

### (b) Description of the Related Art

In an electron system implementing a data storage, a semiconductor device capable of storing high-capacity data is in demand. Accordingly, a method for increasing a data storage capacity of a semiconductor device is being researched. As one method for increasing the data storage capacity of a semiconductor device, a semiconductor device including three-dimensionally arranged memory cells instead of two-dimensionally arranged memory cells has been proposed.

### SUMMARY

The present disclosure attempts to provide a semiconductor device capable of enhancing performance and productivity and a manufacturing method of the same, and an electronic system including a semiconductor device.

A semiconductor device according to an embodiment includes a gate stacking structure, the gate stacking structure including a plurality of interlayer insulation layers and a plurality of gate electrodes alternately stacked with each other on a substrate, the plurality of gate electrodes including a selection gate electrode; a plurality of channel structures extending in a direction crossing the substrate such that the plurality of channel structures penetrate the gate stacking structure, each of the plurality of channel structures including a gate dielectric layer and a channel layer; and at least one separation pattern separating the selection gate electrode at one surface of the gate stacking structure. The plurality of channel structures may an adjacent channel structure adjacent to the at least one separation pattern, wherein the adjacent channel structure includes a first portion having an adjacent surface adjacent to the separation pattern and having a separation surface spaced apart from the separation pattern. At least one of the gate dielectric layer or the channel layer, in the first portion of the adjacent channel structure, may be on the separation surface and the adjacent surface.

An electronic system according to an embodiment includes a main substrate, the semiconductor device on the main substrate, and a controller electrically connected to the semiconductor device on the main board. The semiconductor device may include a gate stacking structure, the gate stacking structure including a plurality of interlayer insulation layers and a plurality of gate electrodes alternately stacked with each other on a substrate, the plurality of gate electrodes including a selection gate electrode; a plurality of channel structures extending in a direction crossing the substrate such that the plurality of channel structures penetrate the gate stacking structure, each of the plurality of channel structures including a gate dielectric layer and a channel layer; and at least one separation pattern separating the selection gate electrode at one surface of the gate stacking structure, wherein the plurality of channel structures includes an adjacent channel structure adjacent to the at least one separation pattern, the adjacent channel structure includes a first portion having an adjacent surface adjacent to the separation pattern and having a separation surface spaced apart from the separation pattern, and at least one of the gate dielectric layer or the channel layer, in the first portion of the adjacent channel structure, is on the separation surface and the adjacent surface.

A manufacturing method of a semiconductor device according to an embodiment includes forming a stacking structure, forming a plurality of preliminary channel structures penetrating the stacking structure, forming a separation pattern by forming an opening for the separation pattern to overlap at least one of the plurality of preliminary channel structures and filling at least a partial portion of the opening for the separation pattern with an insulating material, and removing the plurality of preliminary channel structures and forming a plurality of channel structures.

According to an embodiment, a gate dielectric layer and/or a channel layer may be continuous in a first portion of an adjacent channel structure that is a channel structure partially cut by a separation pattern. As a result, voltage may be uniformly applied to an entire portion of the adjacent channel structure. Accordingly, the adjacent channel structure may stably act as a memory cell string, thereby improving performance and productivity of a semiconductor device.

### BRIEF DESCRIPTION OF THE DRAWINGS

FIG. 1 is a cross-sectional view schematically illustrating a semiconductor device according to at least one embodiment.

FIG. 2 is an enlarged cross-sectional view illustrating an example of a channel structure included in the semiconductor device illustrated in FIG. 1.

FIG. 3 is an enlarged plan view illustrating a partial portion of a cell array region of the semiconductor device illustrated in FIG. 1.

FIG. 4A to FIG. 4C are enlarged plan views of a portion B and a portion C in FIG. 3.

FIG. 5 is a partial cross-sectional view illustrating a separation pattern and an adjacent channel structure included in a semiconductor device according to a modified embodiment.

FIG. 6 is a partial cross-sectional view illustrating a separation pattern and an adjacent channel structure included in a semiconductor device according to a modified embodiment.

FIG. 7 to FIG. 12 are cross-sectional views illustrating a manufacturing method of a semiconductor device according to at least one embodiment.

FIG. 13 is a cross-sectional view illustrating a semiconductor device according to at least one embodiment.

FIG. 14 to FIG. 18 are cross-sectional views illustrating a manufacturing method of a semiconductor device according to at least one embodiment.

FIG. 19 is a cross-sectional view schematically illustrating a semiconductor device according to at least one embodiment.

FIG. 20A to FIG. 20C are plan views of channel structures included in the semiconductor device illustrated in FIG. 19.

FIG. 21 to FIG. 25 are cross-sectional views illustrating a manufacturing method of a semiconductor device according to at least one embodiment.

FIG. 26 is a cross-sectional view schematically illustrating a semiconductor device according to at least one embodiment.

FIG. 27 is a view schematically illustrating an electronic system including a semiconductor device according to at least one embodiment.

FIG. 28 is a view schematically illustrating an electronic system including a semiconductor device according to at least one embodiment.

FIG. 29 is a perspective view schematically illustrating a semiconductor package including a semiconductor device according to at least one embodiment.

FIG. 30 is a perspective view schematically illustrating a semiconductor package including a semiconductor device according to at least one embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiment provided herein.

A portion unrelated to the description is omitted in order to clearly describe the present disclosure, and the same or similar components are denoted by the same reference numeral throughout the present specification.

Further, the sizes and thicknesses of portions, regions, members, units, layers, films, etc. illustrated in the accompanying drawings are not to scale, but are illustrated for better understanding and convenience of explanation, therefore the present disclosure is not limited to the illustrated sizes and thicknesses. In other words, in the drawings, thicknesses of portions, regions, members, units, layers, films, etc. may be enlarged or exaggerated for convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity. For example, it will be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

In addition, unless explicitly described to the contrary, the word “comprise” or “include,” and variations such as “comprises,” “comprising,” “includes,” or “including”, will be understood to imply the inclusion of stated elements but not the exclusion of any other elements.

Further, throughout the specification, a phrase “on a plane,” “in a plane,” “on a plan view,” or “in a plan view” may indicate a case where a portion is viewed from above or a top portion, and a phrase “on a cross-section” or “in a cross-sectional view” may indicate a vertical cross-sectional viewed from a side.

Additionally, functional elements, including elements that process at least one function or operation, may be implemented as processing circuitry such as hardware, software, or a combination of hardware and software, unless expressly indicated otherwise. For example, the processing circuitry more specifically may include, but is not limited to, electrical components such as at least one of transistors, resistors, capacitors, etc., and/or electronic circuits including said components, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

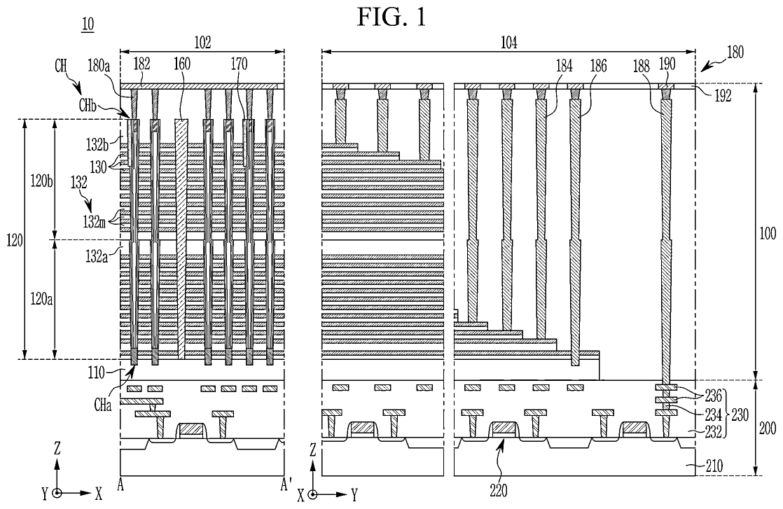

Hereinafter, with reference to FIG. 1 to FIG. 6, a semiconductor device and a manufacturing method of the same according to embodiments and modified embodiments will be described in detail.

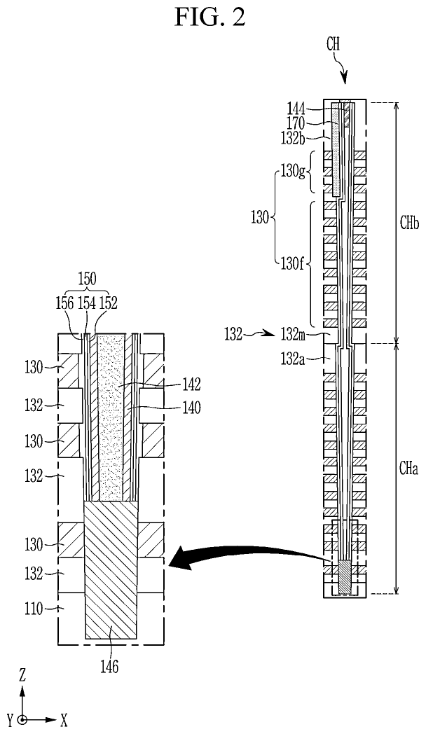

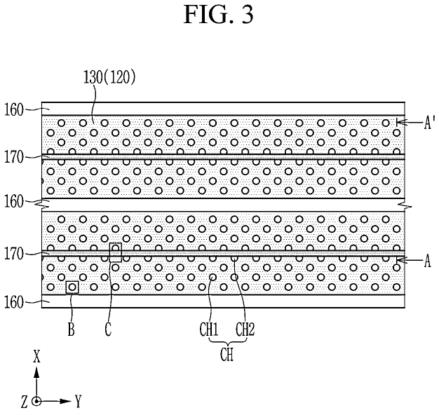

FIG. 1 is a cross-sectional view schematically illustrating a semiconductor device according to at least one embodiment. FIG. 2 is an enlarged cross-sectional view illustrating an example of a channel structure included in the semiconductor device illustrated in FIG. 1. FIG. 3 is an enlarged plan view illustrating a partial portion of a cell array region of the semiconductor device illustrated in FIG. 1. A cross-sectional view of the cell array region 102 taken along a line A-A′ of FIG. 3 is illustrated as corresponding to a cell array region 102 of FIG. 1.

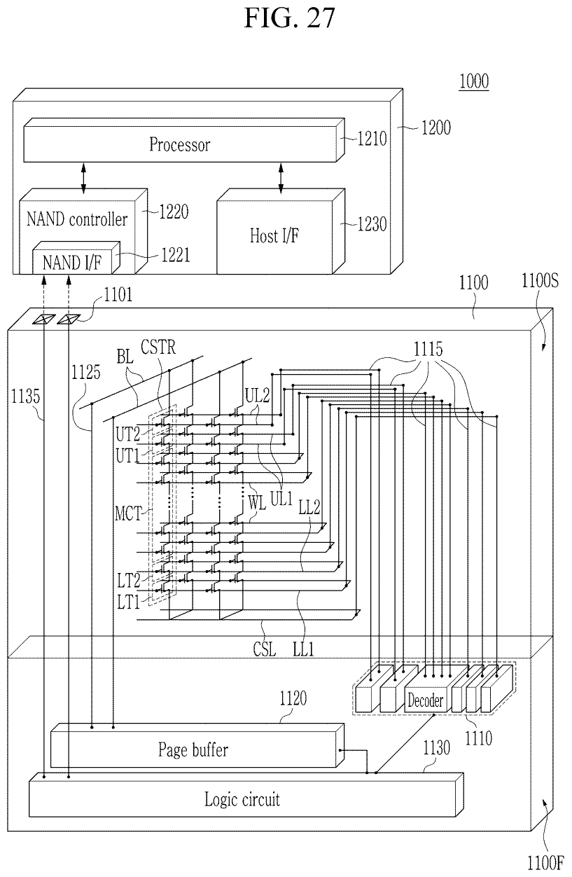

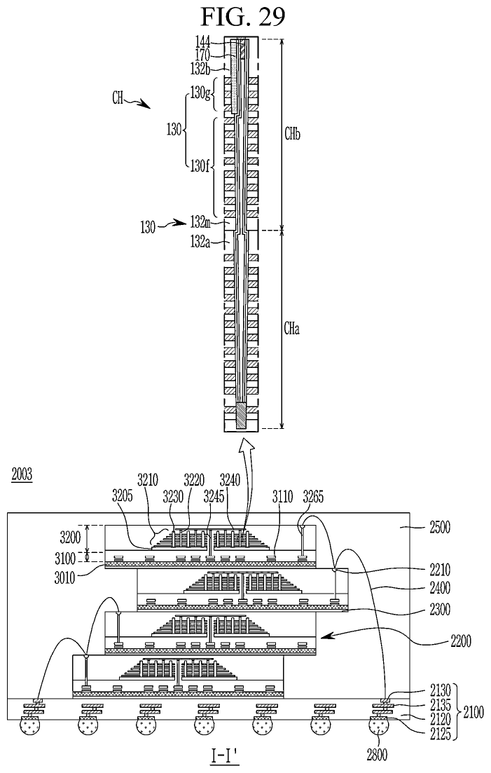

Referring to FIG. 1 to FIG. 3, a semiconductor device 10 according to at least one embodiment may include a cell region 100 (including a memory cell structure) and a circuit region 200 (including a peripheral circuit structure controlling an operation of the memory cell structure). For example, the circuit region 200 and the cell region 100 may correspond to a first structure 1100F and a second structure 1100S of a semiconductor device 1100 included in an electronic system 1000 illustrated in FIG. 27, respectively; and/or, the circuit region 200 and the cell region 100 may be portions including a first structure 3100 and a second structure 3200 of a semiconductor chip 2200 illustrated in FIG. 29, respectively.

Here, the circuit region 200 may include the peripheral circuit structure on a first substrate 210, and the cell region 100 may include a gate stacking structure 120 and a channel structure CH on a second substrate 110 as the memory cell structure. The circuit region 200 may include a first wiring portion 230, and the cell region 100 may include a second wiring portion 180 electrically connected to the memory cell structure.

In at least one embodiment, the cell region 100 may be on the circuit region 200. Accordingly, an area corresponding to the circuit region 200 does not need to be secured separately from the cell region 100. Therefore, an area of the semiconductor device 10 may be reduced. However, the embodiments are not limited thereto, and, in some embodiments, the circuit region 200 may be disposed next to the cell region 100. Various other modifications are possible.

The circuit region 200 may include a circuit element 220 and the first wiring portion 230 on the first substrate 210.

The first substrate 210 may be a semiconductor substrate including a semiconductor material. The semiconductor material may be an elemental semiconductor (e.g., silicon or germanium) and/or a compound semiconductor (e.g., a Group III-V, II-VI, and/or IV-IV semiconductor). For example, the first substrate 210 may be a semiconductor substrate including and/or formed of a semiconductor material and/or may be a substrate in which a semiconductor layer is on a base substrate. For example, the first substrate 210 may include single-crystalline or polycrystalline silicon, epitaxial silicon, germanium, silicon-germanium, silicon on insulator (SOI), germanium on insulator (GOI), and/or the like.

The circuit element 220 on the first substrate 210 may include any of various circuit elements that control an operation of the memory cell structure in the cell region 100. For example, the circuit element 220 may constitute the peripheral circuit structure such as a decoder circuit 1110 (refer to FIG. 27), a page buffer 1120 (refer to FIG. 27), a logic circuit 1130 (refer to FIG. 27), and/or the like.

The circuit element 220 may include, for example, a transistor, but the embodiments are not limited thereto. For example, the circuit element 220 may include not only an active element such as the transistor and/or the like but also a passive element such as a capacitor, a resistor, an inductor, and/or the like.

The first wiring portion 230 on the first substrate 210 may be electrically connected to the circuit element 220. In at least one embodiment, the first wiring portion 230 may include a plurality of wiring layers 236 that are spaced apart from each other while interposing a first insulation layer 232 therebetween and are electrically connected by a contact via 234 to form a desired path. The wiring layer 236 and/or the contact via 234 may include a conductive material (e.g., electrically conductive materials), and the first insulation layer 232 may include an insulating material (e.g., electrically insulating materials). For example, among the plurality of wiring layers 236, a wiring layer 236 at an uppermost portion adjacent to the cell region 100 may include or constitute a pad portion to which a gate contact portion 184, a source contact portion 186, a through plug 188, and/or the like is connected.

The cell region 100 may include a cell array region 102 and a connection region 104. The gate stacking structure 120 and the channel structure CH may be on the second substrate 110 in the cell array region 102. A structure that connects the gate stacking structure 120 and/or the channel structure CH in the cell array region 102 to the circuit region 200 and/or an external circuit may be included in the cell array region 102 and/or the connection region 104.

In at least one embodiment, the second substrate 110 may include a semiconductor layer including a semiconductor material. For example, the second substrate 110 may be a semiconductor substrate including or formed of a semiconductor material and/or may be a substrate in which a semiconductor layer is on a base substrate. For example, the second substrate 110 may include or be formed of silicon, germanium, silicon-germanium, silicon on insulator, germanium on insulator, and/or the like as a base material. The base semiconductor material of the second substrate 110 may be the same and/or different from the semiconductor material of the first substrate 210. In the second substrate 110, a p-type dopant (such as boron (B), gallium (Ga), or the like), or an n-type dopant (such as include phosphorus (P), arsenic (As), or the like) may be doped to the base semiconductor material. However, the embodiments are not limited to a material of the second substrate 110, a conductive type of the dopant doped to the semiconductor layer, or the like.

In the cell array region 102, the gate stacking structure 120 and the channel structure CH may be positioned. The gate stacking structure 120 may include cell insulation layers 132 and gate electrodes 130 alternately stacked on a first surface (e.g., a front surface or an upper surface) of the second substrate 110. The channel structure CH may extend in a direction crossing the second substrate 110 (a Z-axis direction in the drawings) while penetrating the gate stacking structure 120.

The cell insulation layer 132 may include an interlayer insulation layer 132m and an upper insulation layer 132a or 132b. The interlayer insulation layer 132m may be between two gate electrodes 130 adjacent to each other in each of a plurality of the gate stacking structures 120a and 120b. The upper insulation layers 132a and 132b may be at upper surfaces of the plurality of the gate stacking structures 120a and 120b, respectively. In at least one embodiment, thicknesses of the plurality of cell insulation layers 132 may be different. For example, a thickness of the upper insulation layer 132a and/or 132b may be greater than a thickness of the interlayer insulation layer 132m. For simple illustration, it is illustrated, as an example, in FIG. 1 that the cell insulation layer 132 is provided as one without a boundary in a partial portion of the connection region 104. However, one or a plurality of insulation layers having various stacking structures may be in the connection region 104. A shape, a structure, or the like of the cell insulation layer 132 may be variously modified according to some embodiments.

The gate electrode 130 may include any of various conductive materials. For example, the gate electrode 130 may include a metal material (e.g., tungsten (W), copper (Cu), aluminum (Al), or the like), polycrystalline silicon, metal nitride (e.g., titanium nitride (TiN), tantalum nitride (TaN), or the like), and/or a combination thereof. The cell insulation layer 132 may include any of various insulating materials. For example, the cell insulation layer 132 may include silicon oxide, silicon nitride, silicon oxynitride, a low dielectric constant material having a lower dielectric constant than silicon oxide, and/or a combination thereof.

In at least one embodiment, the channel structure CH may be provided. The channel structure CH may extend in a direction crossing the second substrate 110 (e.g., a direction perpendicular to the second substrate 110 or the Z-axis direction in the drawings) to penetrate the gate stacking structure 120.

The channel structure CH may include a channel layer 140, and a gate dielectric layer 150 on the channel layer 140 between the gate electrode 130 and the channel layer 140. The channel structure CH may further include a core insulation layer 142 at an inside of the channel layer 140. In some embodiments, the core insulation layer 142 might not be provided. The channel structure CH may further include a channel pad 144 on the channel layer 140 and/or the core insulation layer 142, and a semiconductor pattern 146 adjacent to the second substrate 110. The gate dielectric layer 150 between the gate electrode 130 and the channel layer 140 may include a tunneling layer 152, a charge storage layer 154, and a blocking layer 156 sequentially on the channel layer 140.

Each channel structure CH forms one memory cell string, and a plurality of channel structures CH may be spaced apart from each other while forming rows and columns, and/or a hexagonal grid in a plan view. For example, a plurality of channel structures CH may be disposed to form any of various shapes such as a lattice shape, a zigzag shape, and/or the like in a plan view. The channel structure CH may have a pillar shape in a cross-sectional view. However, the embodiments are not limited thereto, and an arrangement, a structure, a shape, or the like of the channel structure CH may be variously modified.

The channel layer 140 may include a semiconductor material (e.g., polycrystalline silicon). The core insulation layer 142 may include any of various insulating materials. For example, the core insulation layer 142 may include silicon oxide, silicon nitride, silicon oxynitride, and/or a combination thereof.

The tunneling layer 152 may include an insulating material that is selected to tunnel a charge (e.g., silicon oxide, silicon oxynitride, or the like). The charge storage layer 154 may be used as a data storage region, and the charge storage layer 154 may include polycrystalline silicon, silicon nitride, or the like. The blocking layer 156 may include an insulating material that is selected to prevent an undesirable flow of charge into the gate electrode 130. The blocking layer 156 may include, for example, silicon oxide, silicon nitride, silicon oxynitride, a high dielectric constant material having a higher dielectric constant than silicon oxide, and/or a combination thereof.

However, materials, stacking structures, or the like of the channel layer 140, the core insulation layer 142, and the gate dielectric layer 150 may be variously modified, and the embodiments are not limited thereto.

The channel pad 144 may cover an upper surface of the core insulation layer 142 and be disposed to be electrically connected to the channel layer 140. The channel pad 144 may include a conductive material (e.g., polycrystalline silicon doped with a dopant), but the embodiments are not limited thereto.

The semiconductor pattern 146 may be disposed to be electrically connected to the channel layer 140. The semiconductor pattern 146 may be on and/or in the second substrate 110 and may be on a side surface of at least one gate electrode 130. The semiconductor pattern 146 may act as a channel similar to the channel layer 140.

The semiconductor pattern 146 may include, for example, doped or undoped epitaxial silicon, epitaxial germanium, polycrystalline silicon, single-crystalline silicon, polycrystalline germanium, or single-crystalline germanium. The semiconductor pattern 146 may be an epitaxial layer formed using a selective epitaxial process (SEG). The semiconductor pattern 146 may include a single layer or a plurality of layers.

However, the embodiments are not limited to an electrical connection structure of the channel structure CH and the second substrate 110. In some embodiments, a horizontal conductive layer electrically connected to (e.g., in contact with) the channel layer 140 may be on a side surface of the channel structure CH. Various other modifications are possible.

In at least one embodiment, the gate stacking structure 120 may include the plurality of gate stacking structures 120a and 120b sequentially stacked on the second substrate 110. Then, a number of stacked gate electrodes 130 may be increased and thus a number of memory cells may be increased with a stable structure. In the drawings, it is illustrated as an example that the gate stacking structure 120 includes first and second gate stacking structures 120a and 120b. However, the embodiments are not limited thereto. In some embodiments, the gate stacking structure 120 may include one gate stacking structure or three or more gate stacking structures.

When the plurality of gate stacking structures 120a and 120b are provided as in the above, the channel structure CH may include a plurality of channel structures CHa and CHb that respectively penetrate the plurality of gate stacking structures 120a and 120b. The plurality of channel structures CHa and CHb may have a shape that the plurality of channel structures CHa and CHb are connected to each other. In a cross-sectional view, each of the plurality of channel structures CHa and CHb may have an inclined side surface such that a width of each of the plurality of channel structures CHa and CHb decreases toward the second substrate 110 according to an aspect ratio. A bent portion due to a difference in widths of the plurality of channel structures CHa and CHb may be provided at a connection portion of the plurality of channel structures CHa and CHb. In some embodiments, the plurality of channel structures CHa and CHb may have an inclined side surface that is continuously extended without the bent portion. In FIG. 3, an example that the gate dielectric layer 150, the channel layer 140, and the core insulation layer 142 of the plurality of channel structures CHa and CHb continuously extend to have an integral structure is illustrated. However, the embodiments are not limited thereto. In some embodiments, the gate dielectric layer 150, the channel layer 140, and the core insulation layer 142 of the plurality of channel structures CHa and CHb may be separately formed and be electrically connected to each other. In some embodiments, a separate channel pad may be additionally at a connection portion of the plurality of channel structures CHa and CHb. As such, the embodiments are not limited to a shape of a plurality of channel structures CHa and CHb.

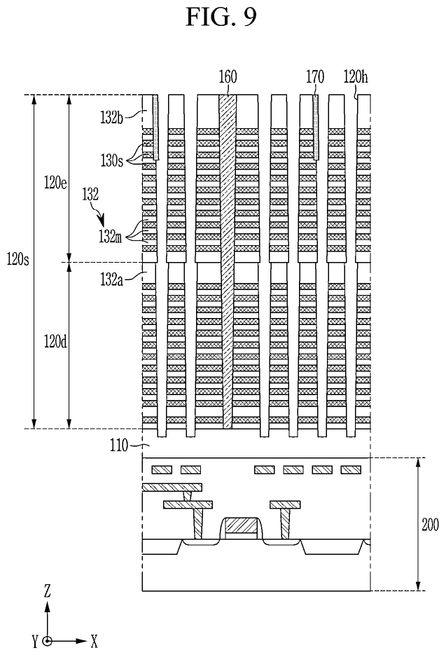

In an enlarged portion of FIG. 2, it is illustrated as an example that a first side surface adjacent to the gate electrode 130 and a second side surface adjacent to the cell insulation layer 132 may be on different planes at a side surface (e.g., the separation surface S1) of the channel structure CH. For example, at the side surface of the channel structure CH, the first side surface may protrude than the second side to have a step portion between the first side surface and the second side surface. This is because the gate electrode 130 is formed by using a penetrating portion 120h (refer to FIG. 9) for forming the channel structure CH. This will be described in detail in a manufacturing method of the semiconductor device 10. However, the embodiments are not limited thereto, and the first surface and the second surface may be on the same plane. Various other modifications are possible.

In at least one embodiment, the gate stacking structure 120 may be divided into a plurality of portions in a plan view by a separation structure 160 extending in a direction crossing the second substrate 110 (e.g., in a direction perpendicular to the second substrate 110 or the Z-axis direction in the drawings) to penetrate the gate stacking structure 120. A separation pattern 170 may be at a portion adjacent to one surface (e.g., an upper portion) of the gate stacking structure 120. In a plan view, a plurality of separation structures 160 and/or a plurality of separation patterns 170 may extend in a first direction (a Y-axis direction in the drawings) and be spaced apart from each other at a predetermined interval in a second direction (an X-axis direction in the drawings) that is transverse to the first direction.

In a plan view, the plurality of gate stacking structures 120 may each extend in the first direction (the Y-axis direction of the drawing) and spaced apart from each other at a predetermined interval in the second direction (the X-axis direction of the drawing) by the separation structure 160. The gate stacking structure 120 divided by the separation structure 160 may constitute one memory cell block. However, the embodiments are not limited thereto, and a range of the memory cell block is not limited thereto.

For example, the separation structure 160 may penetrate the gate stacking structure 120 and extend to the second substrate 110, and the separation pattern 170 may separate one or a part of the plurality of gate electrodes 130. The separation pattern 170 may be between the separation structures 160. In this instance, the gate electrode 130 separated by the separation pattern 170 may be referred to as a selection gate electrode 130g, and the gate electrode 130 where the separation pattern 170 is not positioned may be referred to as a base gate electrode 130f. In this instance, the selection gate electrode 130g may include a string selection gate electrode that selects a string, and the separation pattern 170 may be a string separation pattern that separates the string. In some embodiments, the selection gate electrode 130g may further include a gate electrode other than the string selection gate electrode that selects the string.

For example, in a cross-sectional view, the separation structure 160 may have an inclined side surface such that a width of the separation structure 160 gradually decreases toward the second substrate 110 due to a high aspect ratio. However, the embodiments are not limited thereto. A side surface of the separation structure 160 may be perpendicular to the second substrate 110, or the separation structure 160 may have a bent portion at a connection portion of the first and second gate stacking structures 120a and 120b.

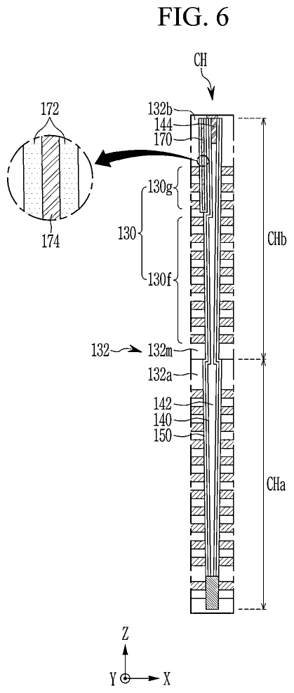

The separation structure 160 and/or the separation pattern 170 may be filled with any of various insulating materials. For example, the separation structure 160 or the separation pattern 170 may include an insulating material such as silicon oxide, silicon nitride, or silicon oxynitride. However, the embodiments are not limited thereto, and a structure, a shape, a material, or the like of the separation structure 160 or the separation pattern 170 may be variously modified. In at least one embodiment, it is described as an example that the separation pattern 170 may include an insulating separation pattern of an insulating material. At least one embodiment different from the above will be described later with reference to FIG. 6.

The connection region 104 and the second wiring portion 180 may be provided to connect the gate stacking structure 120 and the channel structure CH in the cell array region 102 to the circuit region 200 or an external circuit. The connection region 104 may be at a periphery of the cell array region 102 and a partial portion of the second wiring portion 180 may be in the connection region 104.

The second wiring portion 180 may include a member electrically connecting the gate electrode 130, the channel structure CH, and/or the second substrate 110 to the circuit region 200 or the external circuit. For example, the second wiring portion 180 may include a bit line 182, a gate contact portion 184, a source contact portion 186, a through plug 188, a contact via 180a connected to each of the bit line 182, the gate contact portion 184, the source contact portion 186, and/or a through plug 188, and a connection wiring 190 connecting the bit line 182, the gate contact portion 184, the source contact portion 186, the through plug 188, and the contact via 180a.

The bit line 182 may be on the cell insulation layer 132 of the gate stacking structure 120 in the cell array region 102. The bit line 182 may extend in the second direction (the X-axis direction in the drawings) that is transverse to the first direction in which the gate electrode 130 extends. The bit line 182 may be electrically connected to the channel structure CH (e.g., the channel pad 144) through the contact via 180a (e.g., a bit line contact via).

In the connection region 104, the plurality of gate electrodes 130 may extend in the first direction (the Y-axis direction in the drawing). Extension lengths of the plurality of gate electrodes 130 may sequentially decrease in a direction away from the second substrate 110. For example, the plurality of gate electrodes 130 may have a stair shape in the connection region 104. In this instance, the plurality of gate electrodes 130 may have a stair shape in one direction or a plurality of directions. In the connection region 104, a plurality of gate contact portions 184 may penetrate the cell insulation layer 132 to be electrically connected to a plurality of gate electrodes 130, respectively. extended to the connection region 104. In the connection region 104, the source contact portion 186 may penetrate the cell insulation layer 132 to be electrically connected to the lowest gate electrode 130 and/or to the second substrate 110. The through plug 188 may penetrate the gate stacking structure 120 and/or may be at an outside of the gate stacking structure 120 to be electrically connected to the first wiring portion 230 of the circuit region 200.

In some embodiments, the gate contact portion 184 may penetrate the cell insulation layer 132 and the gate electrode 130 and extend into the first wiring portion 230 of the circuit region 200. The gate contact portion 184 may include a connection portion connected to a connection gate electrode among the plurality of gate electrodes 130 included in the gate stacking structure 120. The gate contact portion 184 may be insulated from the remaining gate electrodes among the plurality of gate electrodes 130 that should be insulated from the gate contact portion 184 by an insulating material.

The connection wiring 190 may be positioned in the cell array area 102 and/or the connection area 104. The bit line 182, the gate contact portion 184, the source contact portion 186, and/or the through plug 188 may be electrically connected to the connection wiring 190. For example, the gate contact portion 184, the source contact portion 186, and/or through plug 188 may be connected to the connection wiring 190 through the contact via 180a. However, the embodiments are not limited thereto.

In FIG. 1, an example that the connection wiring 190 is a single layer on the same plane as the bit line 182 and a second insulation layer 192 is at a portion other than the connection wiring 190 is illustrated. However, this is an example illustration for convenience. For example, for an electrical connection with the bit line 182, the gate contact portion 184, the source contact portion 186, and/or the through plug 188, the connection wiring 190 may include a plurality of wiring layers and may further include a contact via.

By the second wiring portion 180 and the first wiring portion 230, the bit line 182 connected to the channel structure CH, the gate electrode 130, and/or the second substrate 110 may be electrically connected to the circuit element 220 of the circuit region 200.

In FIG. 1, it is illustrated, as an example, that each of the gate contact portions 184, the source contact portion 186, and/or the through plug 188 has an inclined side surface such that a width of each of the gate contact portion 184, the source contact portion 186, and/or the through plug 188 decreases toward the second substrate 110 due to an aspect ratio and a bent portion is provided at a boundary portion of the plurality of gate stacking structures 120a and 120b in a cross-sectional view. However, the embodiments are not limited thereto. In some embodiments, the gate contact portion 184, the source contact portion 186, and/or the through plug 188 might not include the bent portion at the boundary portion of the plurality of gate stacking structures 120a and 120b. Various other modifications are possible.

In at least one embodiment, the separation pattern 170 may be adjacent to or in contact with a part of the plurality of channel structures CH. For example, a first row of channel structures CH that are at a first position to have a certain interval in the first direction (the Y-axis direction of the drawing) and a second row of channel structures CH that are at a second position different form the first position to have a certain interval in the first direction may be alternately positioned in the second direction (the X-axis direction in the drawing). According to this, the channel structures CH may be densely disposed while securing an interval between the channel structures CH. The separation pattern 170 may be adjacent to or in contact with the plurality of channel structures CH included in the first row at one side of the second direction (the X-axis direction in the drawing), and may be adjacent to or in contact with the plurality of channel structures CH included in the second row at the other side of the second direction (the X-axis direction in the drawing).

In the drawing, an example where one separation pattern 170 is between two separation structures 160 adjacent in the second direction (the X-axis direction of the drawing) is illustrated, but the embodiments are not limited thereto. A plurality of separation patterns 170 may be between two separation structures 160 adjacent in the second direction (the X-axis direction in the drawing).

In at least one embodiment, the plurality of channel structures CH may include a separation channel structure CH1 spaced apart from the separation pattern 170 and an adjacent channel structure CH2 adjacent to and/or in contact with the separation pattern 170. The adjacent channel structure CH2 may be a partially-cut channel structure cut by the separation pattern 170.

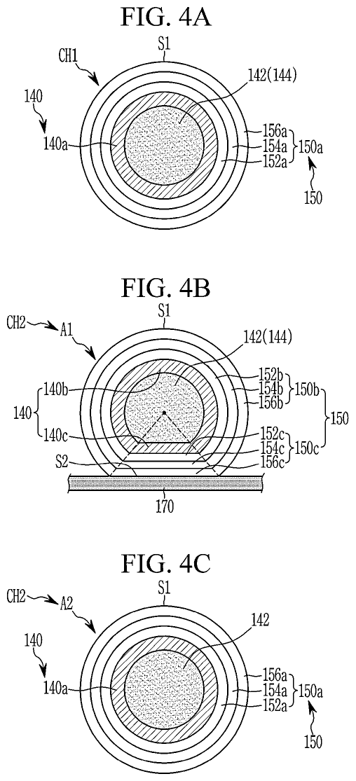

For example, the separation channel structure CH1 that is not adjacent to or in contact with the separation pattern 170 and the adjacent channel structure CH2 that is adjacent to and/or in contact with the separation pattern 170 (e.g., a first portion A1) have different shapes (e.g., different planar shapes) while having the same stacking structure. This will be described in more detail with reference to FIG. 4A to FIG. 4C together with FIGS. 1 to 3.

FIG. 4A to FIG. 4C are enlarged plan views of a portion B and a portion C in FIG. 3. FIG. 4A illustrates the separation channel structure CH1. FIG. 4B illustrates a first portion A1 of the adjacent channel structure CH2. FIG. 4C illustrates a second portion A2 of the adjacent channel structure CH2.

Planar shapes of the separation channel structure CH1, and the first portion A1 and the second portion A2 of the adjacent channel structure CH2 will be described.

Referring to FIG. 4A, in at least one embodiment, a planar shape of the separation channel structure CH1 may be substantially the same and/or substantially similar in an extension direction of the separation channel structure CH1 (the Z-axis direction in the drawing). Here, the phrase that the planar shape is substantially the same may include a case where a size or an area is the same (or similar) as well as a case where there is a difference in size (or area).

The separation channel structure CH1 (e.g., an outer surface of the separation channel structure CH1) may consist of a separation surface S1 spaced apart from the separation pattern 170 in an entire area. Here, the separation surface S1 may be a surface including at least a partial portion of an outer surface of a preliminary penetrating portion or a penetrating portion 120h (refer to FIG. 9) for forming the channel structure CH.

The planar shape of the separation channel structure CH1 may have a symmetrical shape. Here, a symmetrical shape may refer to a case having a symmetrical structure or a symmetrical pattern at both sides in all directions passing through a center. For example, the separation channel structure CH1 may have a planar shape that is symmetrical at both sides in the second direction (the X-axis direction in the drawing) that is transverse to the first direction (the Y-axis direction in the drawing) in which the separation pattern 170 extends.

For example, in a plan view, the separation channel structure CH1 may have an extended shape to maintain the same pattern. In at least one embodiment, in a plan view, the separation channel structure CH1 may have a circular shape due to the separation surface S1. Accordingly, the separation channel structure CH1 may include or consist of a rounded surface.

Referring to FIG. 4B and FIG. 4C, the adjacent channel structure CH2 includes a first portion (e.g., an upper portion) A1 that is in contact with the separation pattern 170 and a second portion (e.g., a lower portion) A2 other than the first portion A1. In at least one embodiment, a planar shape of the first portion A1 may be substantially the same (and/or substantially similar) in an extension direction of the first portion A1 (the Z-axis direction in the drawing), and a planar shape of the second portion A2 may be substantially the same (and/or substantially similar) in the direction in an extension direction of the second portion A2 (the Z-axis direction in the drawing). The first portion A1 and the second part A2 may have different planar shapes.

Referring to FIG. 4B, the first portion A1 (e.g., an outer surface of the first portion A1) of the adjacent channel structure CH2 may include an adjacent surface S2 adjacent to or in contact with the separation pattern 170, and a separation surface S1 other than the adjacent surface S2. The separation surface S1 may include a portion spaced apart from the separation pattern 170 at an opposite side of the separation pattern 170.

The planar shape of the first portion A1 may have an asymmetric shape. Here, an asymmetrical shape may refer to a case having an asymmetrical pattern or an asymmetrical pattern at both sides in at least one direction passing through a center. The planar shape of the adjacent surface S2 of the first portion A1 and the planar shape of the separation surface S1 of the first portion A1 may have an asymmetric shape. For example, the first portion A1 may have a planar shape that is asymmetrical at both sides in the second direction (the X-axis direction in the drawing) that is transverse to the first direction (the Y-axis direction in the drawing) in which the separation pattern 170 extends.

For example, in a plan view, the first portion A1 may include portions having different patterns. In at least one embodiment, in a plan view, the separation surface S1 of the first portion A1 may have an arc shape, and the adjacent surface S2 of the first portion A1 may have a straight line shape connecting both ends of the separation surface S1 of the first portion A1. Accordingly, the separation surface S1 of the first portion A1 may have a rounded surface and the adjacent surface S2 of the first portion A1 may be configured as a flat surface.

Then, an area defined by the separation surface S1 of the first portion A1 and two straight lines connecting both ends of the separation surface S1 and a center of the first portion A1 may have a fan shape, and an area defined by the adjacent surface S2 of the first portion A1 and two straight lines connecting both ends of the adjacent surface S2 and the center of the first portion A1 may have a triangular shape. Here, the center of the first portion A1 may refer to a portion corresponding to a center of the second portion A2.

However, the embodiments are not limited thereto. The adjacent surface S2 of the first portion A1 may connect the both ends of the separation surface S1 in the first portion A1 and may have a rounded shape having a curvature less than a curvature of the separation surface S1 of the first portion A1. The adjacent surface S2 of the first portion A1 may connect the both ends of the separation surface S1 in the first portion A1 and may have a rounded shape having a curvature direction opposite direction to a curvature direction of the separation surface S1 of the first portion A1. For example, in these instances, the adjacent surface S2 of the first portion A1 may have an annular shape connected to the annular shape of the separation surface S1 in the first portion A1 such that an internal angle between the adjacent surface S2 and the separation surface S1 is an acute angle.

In these instances, in a plan view, a length of the separation surface S1 of the first portion A1 may be greater than a length of the adjacent surface S2 of the first portion A1. Here, the length of the separation surface S1 or the adjacent surface S2 may mean the length measured in a state that the separation surface S1 or the adjacent surface S2 is starched in a straight line. In some embodiments, a central angle between the center of the first portion A1 and the two straight lines connecting the both ends of the separation surface S1 of the first portion A1 may be greater than a central angle between the center of the first portion A1 and the two straight lines connecting the both ends of the adjacent surface S2 of the first portion A1. In a plan view, the first portion A1 may have a shape between a semicircular shape and a circular shape. According to this, the first portion A1 may have a planar size greater than a certain level, and thus, the memory cell may be stably secured.

Referring to FIG. 4C, the second portion A2 (e.g., an outer surface of the second portion A2) of the adjacent channel structure CH2 may consist of a separation surface S1 spaced apart from the separation pattern 170 in an entire area.

The planar shape of the second portion A2 may have a symmetrical shape. For example, the second portion A2 may have a planar shape that is symmetrical at both sides in the second direction (the X-axis direction in the drawing) that is transverse to the first direction (the Y-axis direction in the drawing) in which the separation pattern 170 extends.

For example, in a plan view, the second portion A2 may have an extended shape to maintain the same pattern. In at least one embodiment, in a plan view, the second portion A2 may have a circular shape due to the separation surface S1. Accordingly, the separation surface S1 may include or consist of a rounded surface.

A stacking order in the separation channel structure CH1 and the first portion A1 and the second portion A2 of the adjacent channel structure CH2 will be described.

Referring to FIG. 4A, in at least one embodiment, in the separation channel structure CH1, the gate dielectric layer 150 and the channel layer 140 are sequentially on the separation surface S1, and the core insulation layer 142 may be at an inside of the channel layer 140. In this instance, a dielectric portion 150a may include a blocking portion 156a, a charge storage portion 154a, and a tunneling portion 152a that are sequentially stacked.

For example, in the separation channel structure CH1, the dielectric portion 150a may be continuously and entirely on the separation surface S1, the channel portion 140a may be continuously and entirely on the dielectric portion 150a, and the core insulation layer 142 may be at the inside of the channel layer 140.

In at least one embodiment, the gate dielectric layer 150 and/or the channel layer 140 may be at both sides of the separation channel structure CH1 in all directions passing through a center of the separation channel structure CH1. For example, in one direction passing through the center of the separation channel structure CH1, the gate dielectric layer 150, the channel layer 140, the core insulation layer 142, the channel layer 140, and the gate dielectric layer 150 may be sequentially disposed.

In at least one embodiment, the dielectric portion 150a may have a symmetrical shape in a plan view. In one embodiment, in a plan view, the dielectric portion 150a may have an annular shape, and the channel portion 140a may have an annular shape.

Referring to FIG. 4B, in at least one embodiment, in the first portion A1 of the adjacent channel structure CH2, at least one of the gate dielectric layer 150 or the channel layer 140 may be on the adjacent surface S2. More particularly, in the first portion A1, the gate dielectric layer 150 and the channel layer 140 may be on the separation surface S1 and the adjacent surface S2, and the core insulation layer 142 may be at an inside of the channel layer 140.

That is, in the first portion A1, the gate dielectric layer 150 may include a first dielectric portion 150b and a second dielectric portion 150c. The first dielectric portion 150b may be on the separation surface S1, and the second dielectric portion 150c may be connected to the first dielectric portion 150b on the adjacent surface S2. In the first portion A1 of the adjacent channel structure CH2, the channel layer 140 may include a first channel portion 140b and a second channel portion 140c. The first channel portion 140b may be on the first dielectric portion 150b on the separation surface S1. The second channel portion 140c may be connected to the first channel portion 140b on the second dielectric portion 150c on the adjacent surface S2.

In these instances, the first dielectric portion 150b may include a first blocking portion 156b, a first charge storage portion 154b, and a first tunneling portion 152b that are sequentially stacked. The second dielectric portion 150c may include a second blocking portion 156c, a second charge storage portion 154c, and a second tunneling portion 152c that are sequentially stacked. The second blocking portion 156c may be connected to the first blocking portion 156b. The second charge storage portion 154c may be connected to the first charge storage portion 154b. The second tunneling portion 152c may be connected to the first tunneling portion 152b.

In a plan view, the gate dielectric layer 150 may be continuously and entirely in the first portion A1 including the separation surface S1 and the adjacent surface S2 by the first dielectric portion 150b and the second dielectric portion 150c. In a plan view, the channel layer 140 may be continuously and entirely in the first portion A1 including the separation surface S1 and the adjacent surface S2 by the first channel portion 140b and the second channel portion 140c. That is, the gate dielectric layer 150 might not have a cut surface (e.g., cut by the separation pattern 170), and the channel layer 140 might not have a cut surface (e.g., cut by the separation pattern 170).

In at least one embodiment, the gate dielectric layer 150 and/or the channel layer 140 may be at both sides of the first portion A1 in all directions passing through the center of the first portion A1. For example, in one direction passing through the center of the first portion A1, the gate dielectric layer 150, the channel layer 140, the core insulation layer 142, the channel layer 140, and the gate dielectric layer 150 may be sequentially disposed.

In at least one embodiment, in a plan view, the first dielectric portion 150b and the second dielectric portion 150c may have an asymmetrical shape, and the first channel portion 140b and the second channel portion 140c may have an asymmetrical shape. This may be because the planar shape of the first portion A1, or the planar shape of the adjacent surface S2 and the separation surface S1 in the first portion A1 may have an asymmetrical shape in a plan view.

In at least one embodiment, in a plan view, the first dielectric portion 150b may have or consist of a part of an annular shape, and the second dielectric portion 150c may have a shape (for example, a straight shape or a line shape) different from the shape of the first dielectric portion 150b. In a plan view, the first channel portion 140b may have (and/or consist of) a part of an annular shape, and the second channel portion 140c may have a shape (for example, a straight shape or a line shape) different from the shape of the first channel portion 140b.

An area of the first dielectric portion 150b may be greater than an area of the second dielectric portion 150c, and an area of the first channel portion 140b may be greater than an area of the second channel portion 140c. This may be because the length of the separation surface S1 of the first portion A1 is greater than the length of the adjacent surface S2 of the second portion A2 in a plan view. Accordingly, each of the gate dielectric layer 150 and the channel layer 140 in the first portion A1 may have a planar size greater than a certain level, and thus, the memory cell may be stably secured.

Accordingly, the gate dielectric layer 150 and/or the channel layer 140 may be at the both sides of the adjacent channel structure CH2 in all directions passing through the center of the adjacent channel structure CH2. For example, in one direction passing through the center of the adjacent channel structure CH2, the gate dielectric layer 150, the channel layer 140, the core insulation layer 142, the channel layer 140, and the gate dielectric layer 150 may be sequentially disposed. Accordingly, the core insulation layer 142 in the first portion A1 may be entirely spaced apart from the separation pattern 170 interposing the gate dielectric layer 150 and/or the channel layer 140 therebetween.

Referring to FIG. 4C, in at least one embodiment, the second portion A2 of the adjacent channel structure CH2 may be included in the adjacent channel structure CH2, but the separation pattern 170 is not at the second portion A2 of the adjacent channel structure CH2. The second portion A2 of the adjacent channel structure CH2 may have substantially the same shape or structure as the separation channel structure CH1.

In at least one embodiment, in the second portion A2, the gate dielectric layer 150 and the channel layer 140 may be sequentially on the separation surface S1, and the core insulation layer 142 may be at an inside of the channel layer 140. In this instance, a dielectric portion 150a may include a blocking portion 156a, a charge storage portion 154a, and a tunneling portion 152a that are sequentially stacked.

For example, in the second portion A2, the dielectric portion 150a may be continuously and entirely on the separation surface S1, the channel portion 140a may be continuously and entirely on the dielectric portion 150a, and the core insulation layer 142 may be at the inside of the channel layer 140.

In at least one embodiment, the gate dielectric layer 150 and/or the channel layer 140 may be at both sides of the second portion A2 in all directions passing through a center of the second portion A2. For example, in one direction passing through the center of the second portion A2, the gate dielectric layer 150, the channel layer 140, the core insulation layer 142, the channel layer 140, and the gate dielectric layer 150 may be sequentially disposed.

In the at least one embodiment, the dielectric portion 150a of the second portion A2 may be connected to the first dielectric portion 150b and the second dielectric portion 150c of the first portion A1, and the channel portion 140a of the second portion A2 may be connected to the first channel portion 140b and the second channel portion 140c of the first portion A1. Accordingly, in a cross-sectional view, the gate dielectric layer 150 may be continuously in the first portion A1 and the second portion A2, and the channel layer 140 may be continuously in the first portion A1 and the second portion A2.

In at least one embodiment, the dielectric portion 150a may have a symmetrical shape in a plan view. In at least one embodiment, in a plan view, the dielectric portion 150a may have an annular shape, and the channel portion 140a may have an annular shape.

As described above, in a plan view at a portion where the core insulation layer 142 is positioned, in the separation channel structure CH1, the first portion A1 of the adjacent channel structure CH2, and the second portion A2 of the adjacent channel structure CH2, a stacking order of the gate dielectric layer 150, the channel layer 140, and the core insulation layer 142 may be the same. For example, the gate dielectric layer 150, the channel layer 140, the core insulation layer 142, the channel layer 140, and the gate dielectric layer 150 may be sequentially disposed in one direction passing through the center. Here, the stacking order may mean the stacking order in one direction passing through the center of the channel structure CH.

In the above description, the portion where the core insulation layer 142 is positioned is described as an example, but the embodiments are not limited thereto.

In some embodiments, when the core insulation layer 142 is not provided, in a plan view, in the separation channel structure CH1, the first portion A1, and the second portion A2, a stacking order of the gate dielectric layer 150 and the channel layer 140 may be the same.

In some embodiments, in a plan view at a portion where the channel pad 144 is positioned, in the separation channel structure CH1 and the first portion A1 of the adjacent channel structure CH2, a stacking order of the gate dielectric layer 150, the channel layer 140, and the channel pad 144 may be the same. For example, in each of the separation channel structure CH1 and the first portion A1 of the adjacent channel structure CH2, the gate dielectric layer 150, the channel layer 140, the channel pad 144, the channel layer 140, and the gate dielectric layer 150 may be sequentially disposed in one direction passing through the center. In some embodiments, in each of the separation channel structure CH1 and the first portion A1 of the adjacent channel structure CH2, the gate dielectric layer 150, the channel pad 144, and the gate dielectric layer 150 may be sequentially disposed in one direction passing through the center.

In at least one embodiment, in the first portion A1 of the adjacent channel structure CH2, the channel pad 144 may be entirely spaced apart from the separation pattern 170 interposing the gate dielectric layer 150 and/or the channel layer 140 therebetween.

In the above description, it is described as an example that the separation channel structure CH1 or the second portion A2 of the adjacent channel structure CH2 may have a planar shape of a circular shape, and the first portion A1 of the adjacent channel structure CH2 may have a planar shape where a partial portion of the circular shape is removed. However, the embodiments are not limited thereto. The separation channel structure CH1 or the second portion A2 of the adjacent channel structure CH2 may have a planar shape of a polygonal shape, an elliptical shape, an irregular shape, or the like, and the first portion A1 of the adjacent channel structure CH2 may have a planar shape where a partial portion of the separation channel structure CH1 or the second portion A2 is removed. However, the embodiments are not limited thereto.

According to at least one embodiment, the gate dielectric layer 150 and/or the channel layer 140 may be continuous in the first portion A1 of the adjacent channel structure CH2 that is the channel structure partially cut by the separation pattern 170. As a result, voltage may be uniformly applied to an entire portion of the adjacent channel structure CH2. Accordingly, the adjacent channel structure CH2 may stably act as a memory cell string, thereby improving performance and productivity of the semiconductor device 10.

On the other hand, in the conventional channel structure that is partially cut by a separation pattern, a gate dielectric layer and a channel layer has a cut portion or a cut surface. An electric field may be concentrated in the cut portion or the cut surface of the channel layer, and thus, it is difficult to uniformly apply voltage to the change layer. If the conventional channel structure that is partially cut is used as a memory cell string, performance of the memory cell string may be deteriorated. If the conventional channel structure that is partially cut is used not as the memory cell string, a size of a semiconductor device may increase due to a dummy channel structure, thereby reducing productivity.

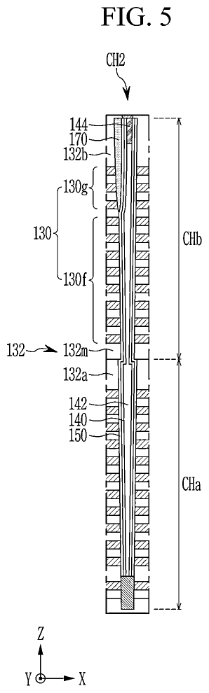

In the drawing, an example where the separation pattern 170 has substantially the same width in a thickness direction of the semiconductor device 10 or an extension direction of the channel structure CH is illustrated. Here, the width of the separation pattern 170 may refer to a width in the second direction (the X-axis direction in the drawing) that is transverse to the first direction (the Y-axis direction in the drawing) in which the separation pattern 170 extends in a plan view. Accordingly, a side surface of the separation pattern 170 adjacent to or in contact with the adjacent channel structure CH2 may have a flat surface. However, the embodiments are not limited thereto. At least one embodiment different form the above will be described with reference to FIG. 5.

In the drawing, an example wherein an upper surface of the separation pattern 170, an upper surface of the separation structure 160, and an upper surface of the channel pad 144 may be on the same plane is illustrated. However, in some embodiments, the upper surface of the separation pattern 170 and the upper surface of the separation structure 160 may be at different positions. The separation pattern 170 may be at a portion where the channel pad 144 is not positioned so that the separation pattern 170 and the channel pad 144 are not adjacent to each other. Various other modifications are possible.

Hereinafter, a semiconductor device according to modified embodiments will be described in detail with reference to FIG. 5 and FIG. 6.

FIG. 5 is a partial cross-sectional view illustrating a separation pattern 170 and an adjacent channel structure CH2 included in a semiconductor device according to a modified embodiment. A portion corresponding to the portion illustrated in FIG. 2 is illustrated in FIG. 5.

As illustrated in FIG. 5, a separation pattern 170 according to a modified embodiment may have a shape where a width gradually decreases toward the second substrate. As an example, a side surface of the separation pattern 170 may have a rounded and/or inclined surface. Then, a gate dielectric layer 150 and a channel layer 140 may be along the rounded surface of an adjacent surface S2 in a first portion A1 of an adjacent channel structure CH2 (e.g., that is adjacent to or in contact with the separation pattern 170). Thus, the gate dielectric layer 150 and the channel layer 140 may be stably on the first portion A1 and the second portion A2. However, the embodiments are not limited thereto. For example, the side surface of the separation pattern 170 may have various shapes, and the gate dielectric layer 150 and the channel layer 140 may be along a side surface of the separation pattern 170 and/or the adjacent surface S2 adjacent to the separation pattern 170.

FIG. 6 is a partial cross-sectional view illustrating a separation pattern 170 and an adjacent channel structure CH2 included in a semiconductor device according to a modified embodiment. A portion corresponding to the portion illustrated in FIG. 2 is illustrated in FIG. 6.

As illustrated in FIG. 6, a separation pattern 170 according to a modified embodiment may include a spacer layer 172 and a conductive layer 174 at an inside of the spacer layer 172. For example, the spacer layer 172 may be at both sides in a second direction (an X-axis direction in the drawing) that is transverse to an extension direction of the separation pattern 170, and the conductive layer 174 may be between the spacer layers 172 at the both sides in the second direction. The shape of the separation pattern 170 illustrated in FIG. 6 may be substantially the same (and/or substantially to) the shape of the separation patterns 170 discussed in relation to FIGS. 2 and 5.

The conductive layer 174 may include a conductive material. For example, the conductive layer 174 may include a metal material (e.g., tungsten (W), copper (Cu), aluminum (Al), or the like), polycrystalline silicon, conductive metal nitride (e.g., titanium nitride (TiN), tantalum nitride (TaN), or the like), and/or a combination thereof. In at least one embodiment, the conductive layer 174 may include the same material as the gate electrode 130. The spacer layer 172 may include an insulating material. For example, the spacer layer 172 may include silicon oxide, silicon nitride, silicon oxynitride, a low dielectric constant material having a lower dielectric constant than silicon oxide, and/or a combination thereof.

Voltage applied to the gate electrode 130 may be applied to the conductive layer 174. Then, the voltage may be uniformly applied to the channel layer 140 in the first portion A1 of the adjacent channel structure CH2 that is in contact with the separation pattern 170. However, the embodiments are not limited thereto. The conductive layer 174 may include or consist of a floating portion to which no voltage is applied.

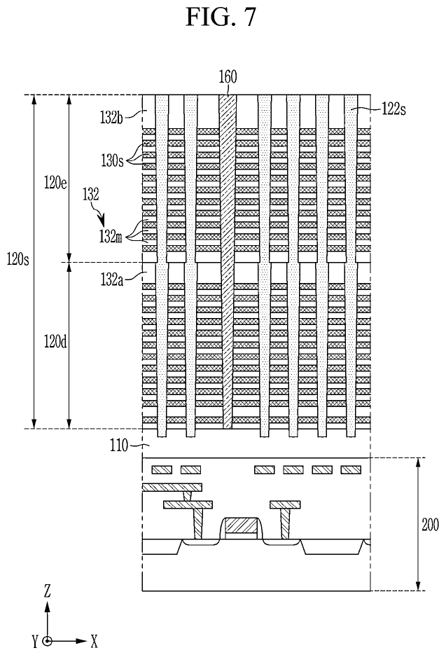

Hereinafter, a manufacturing method of a semiconductor device according to at least one embodiment will be described in more detail with reference to FIGS. 7 to 12. To the extent that an element is not described in detail below, it may be understood that the element is at least substantially similar to (and/or the same as) a corresponding element that has been described elsewhere within the present disclosure. A portion which is not described in the above will be described in detail.

FIG. 7 to FIG. 12 are cross-sectional views illustrating a manufacturing method of a semiconductor device according to at least one embodiment. In FIG. 7 to FIG. 12, a portion corresponding to a left portion of FIG. 1 is illustrated. Hereinafter, a manufacturing method of a semiconductor device 10 will be described mainly based on a gate stacking structure 120, a channel structure CH, a separation structure 160, and a separation pattern 170 in a cell region 100.

As illustrated in FIG. 7, a second substrate 110 and a stacking structure 120s may be formed on a circuit region 200, and a channel sacrificial layer 122s and a separation structure 160 extending to penetrate the stacking structure 120s may be formed. Here, the channel sacrificial layer 122s may be referred to as a preliminary channel structure.

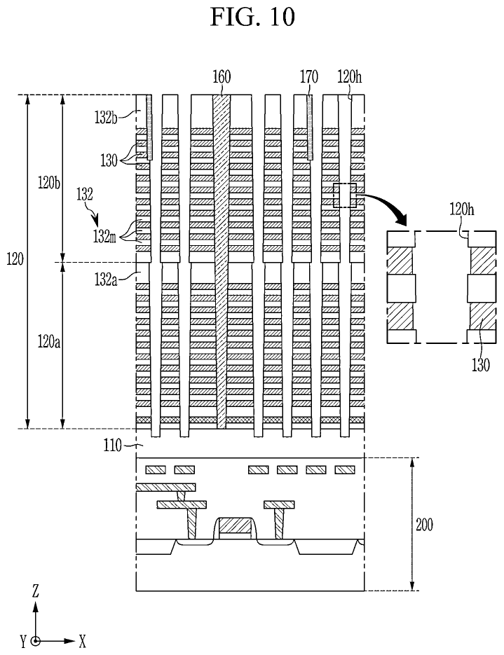

First, the second substrate 110 may be formed on the circuit region 200, and interlayer insulation layers 132m and sacrificial insulation layers 130s may be alternately stacked on the second substrate 110 to form the stacking structure 120s. In this instance, upper insulation layers 132a and 132b may be at an upper portion of each stacking structure 120s. Here, the sacrificial insulation layer 130s may be a layer that will be replaced with a gate electrode 130 (refer to FIG. 10) through a subsequent process, and the sacrificial insulation layer 130s may be formed to correspond to a portion where the gate electrode 130 will be formed.

The sacrificial insulation layer 130s may include a material different from and with an etch selectivity from a material of the interlayer insulation layer 132m. For example, the interlayer insulation layer 132m may include silicon oxide, silicon nitride, silicon oxynitride, a low dielectric constant material, or the like. The sacrificial insulation layer 130s may include at least one of silicon, silicon oxide, silicon carbide, or silicon nitride, and a material different from the material of the interlayer insulation layer 132m.

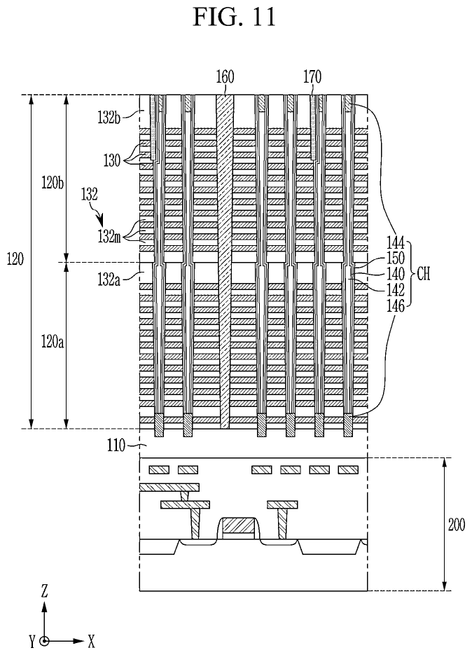

Subsequently, a preliminary penetrating portion that penetrates the stacking structure 120s may be formed at a portion where a channel structure CH (refer to FIG. 11) will be formed, and the preliminary penetrating portion may be filled with a sacrificial material to form the channel sacrificial layer 122s. An opening for a separation structure that penetrate the stacking structure 120s may be formed in an area corresponding to a separation structure 160, and the opening for the separation structure may be filled with an insulating material or the like to form the separation structure 160.

In at least one embodiment, the preliminary penetrating portion may be formed through an etching process (e.g., a plasma etching process and/or the like), and the preliminary penetrating portion may be filled by, e.g., a deposition process and/or the like. The channel sacrificial layer 122s may include at least one of polycrystalline silicon, tungsten, titanium nitride, or carbon. In at least one embodiment, the opening for the separation structure may be formed by an etching process (e.g., a plasma etching process or the like), and the opening for the separation structure may be filled by various processes (e.g., a deposition process or the like).

A formation order of the channel sacrificial layer 122s and the separation structure 160 may be variously modified. For example, the separation structure 160 may be formed after forming the channel sacrificial layer 122s, or the channel sacrificial layer 122s may be formed after forming the separation structure 160. In some embodiments, a part of the process of forming the preliminary penetrating portion and a part of the process of forming the opening of the separation structure may be performed together. In some embodiments, a part of the process of filling the preliminary penetrating portion and a part of the process of filling the opening of the separation structure may be performed together. In at least one embodiment, the channel sacrificial layer 122s and the separation structure 160 may include the same material; or, in at least one embodiment the channel sacrificial layer 122s may include a material with an etch selectivity with a material of the separation structure 160. In this case, at least part of the process of forming and/or filling the preliminary penetrating portion and the opening for the separation structure may be performed together. In some embodiments, the channel sacrificial layer 122s and the separation structure 160 may include different materials.

In at least one embodiment, the stacking structure 120s may include a plurality of stacking structures 120d and 120e sequentially stacked on the second substrate 110. The channel sacrificial layer 122s may include a plurality of channel portions penetrating a plurality of stacking structures 120d and 120e, respectively. However, the embodiments are not limited thereto.

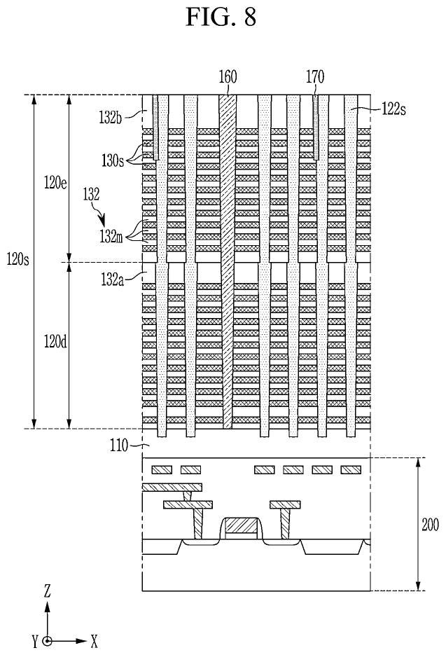

Subsequently, as illustrated in FIG. 8, a separation pattern 170 may be formed at a partial portion of the stacking structure 120s. The separation pattern 170 may be formed by forming an opening for a separation pattern through an etching process using a mask layer and filling at least a partial portion of the opening for the separation pattern with an insulating material. For example, by entirely filling the opening for the separation pattern with the insulating material, an insulating separation pattern illustrated in FIG. 2 may be formed. In some embodiments, by sequentially forming a spacer layer and a conductive layer, a separation pattern illustrated in FIG. 6 may be formed.

For example, the separation pattern 170 that penetrates a selection gate electrode 130g (refer to FIG. 2) may be formed by forming the opening for the separation pattern that penetrates the selection gate electrode 130g.

The process for forming the opening for the separation pattern may be performed by an etching process (e.g., a dry etching process and/or the like). The process for filling the opening for the separation pattern may be performed by any of various processes (e.g., a deposition process or the like).

In at least one embodiment, when forming the opening for the separation pattern, partial portions of the channel sacrificial layers 122s at both sides of the opening for the separation pattern may be removed together. When forming the opening for the separation pattern, a surface exposed at the portion from which the channel sacrificial layer 122s is removed may constitute an adjacent surface S2 (refer to FIG. 4A to FIG. 4C).

The channel sacrificial layer 122s, among the plurality of channel sacrificial layers 122s, that is adjacent to or in contact with the separation pattern 170 may be replaced with an adjacent channel structure CH2 (refer to FIG. 4A to FIG. 4C) in a subsequent process. The channel sacrificial layer 122s, among the plurality of channel sacrificial layers 122s, that is spaced apart from the separation pattern 170 may be replaced with a separation channel structure CH1 (refer to FIG. 4A to FIG. 4C) in a subsequent process.

Subsequently, as illustrated in FIG. 9, the channel sacrificial layer 122s may be removed to form a penetrating portion 120h. The process for forming the penetrating portion 120h may be performed using an etching process (e.g., a dry etching processes). In at least one embodiment, when the channel sacrificial layer 122s includes a material different from a material of the separation structure 160, the channel sacrificial layer 122s and the separation structure 160 have different etch selectivity in an etching process, and thus, the channel sacrificial layer 122s may be selectively removed. In some embodiments, (e.g., when the channel sacrificial layer 122s and the separation structure 160 include the same material and/or materials with similar etching properties) the channel sacrificial layer 122s may be removed using a mask.

Subsequently, as illustrated in FIG. 10, the sacrificial insulation layer 130s (refer to FIG. 9) may be replaced with a gate electrode 130. The sacrificial insulation layer 130s may be selectively removed by an etching process (e.g., a wet etching process) through the penetrating portion 120h. The gate electrode 130 may be formed by filling the portion from which the sacrificial insulation layer 130s was removed with a conductive material. As a result, a horizontal area where the sacrificial insulation layer 130s was positioned may be replaced with the gate electrode 130.

For example, after forming a conductive material layer in the penetrating portion 120h and the horizontal area where the sacrificial insulation layer 130s was positioned, a portion of the conductive material layer within the penetrating portion 120h may be removed to form the gate electrode 130. In this instance, considering imperfections from process errors and/or the like, a portion of the conductive material layer in the horizontal area adjacent to the penetrating portion 120h may be partially etched. Accordingly, as illustrated in an enlarged portion of FIG. 10, a surface of the penetrating portion 120h adjacent to the gate electrode 130 may protrude from a surface adjacent to the cell insulation layer 132. For example, a step portion may be between a first side surface of the penetrating portion 120h adjacent to the gate electrode 130 and a second side surface of the penetrating portion 120h adjacent to the cell insulation layer 132. However, the embodiments are not limited to this. For example, in at least one embodiment, the first side surface of the penetrating portion 120h adjacent to the gate electrode 130 and the second side surface of the penetrating portion 120h adjacent to the cell insulation layer 132 may be on the same plane. Various other modifications are possible.

As a result, a gate stacking structure 120 including the gate electrode 130 and the cell insulation layer 132 may be formed. In at least one embodiment, the gate stacking structure 120 may include a plurality of gate stacking structures 120a and 120b sequentially stacked on the second substrate 110. However, the embodiments are not limited thereto.

Subsequently, as illustrated in FIG. 11, a channel structure CH may be formed in the penetrating portion 120h (refer to FIG. 10).

In at least one embodiment, a semiconductor pattern 146 may be formed at a lower portion of the penetrating portion 120h, a gate dielectric layer 150, a channel layer 140, and a core insulation layer 142 may be sequentially formed at another portion of the penetrating portion 120h, and a channel pad 144 may be formed. The semiconductor pattern 146 may be formed using a selective epitaxial process. The channel layer 140 may be electrically connected to the semiconductor pattern 146 and the channel pad 144. The gate dielectric layer 150, the channel layer 140, the core insulation layer 142, or the channel pad 144 may be formed by, e.g., a deposition process and/or the like.

In at least one embodiment, the channel structure CH may be formed after forming the separation pattern 170. Accordingly, in the forming of the channel structure CH, the gate dielectric layer 150 and the channel layer 140 of the adjacent channel structure CH2 may be formed on the adjacent surface S2 adjacent to the separation pattern 170. Accordingly, in a plan view, the gate dielectric layer 150 may be formed continuously and entirely and the channel layer 140 may be formed continuously and entirely in the adjacent channel structure CH2.

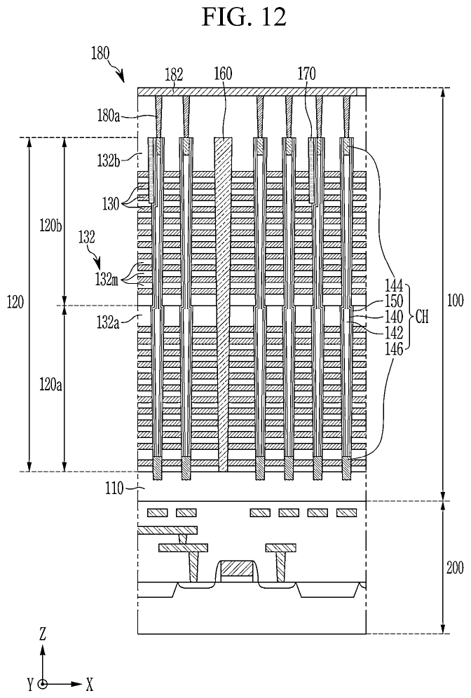

Subsequently, as illustrated in FIG. 12, a second wiring portion 180 (including a bit line 182 connected to the channel structure CH), and/or the like may be further formed.

According to at least one embodiment, after forming the separation pattern 170, the gate dielectric layer 150 and the channel layer 140 of the channel structure CH are formed. Therefore, in the first portion A1 of the adjacent channel structure CH2 adjacent to the separation pattern 170, the gate dielectric layer 150 and the channel layer 140 may be formed continuously without a cut portion and/or a cut surface. Accordingly, the adjacent channel structure CH2 may stably act as a memory cell string and a size of the semiconductor device 10 may be reduced. As a result, performance and productivity of the semiconductor device 10 may be improved.

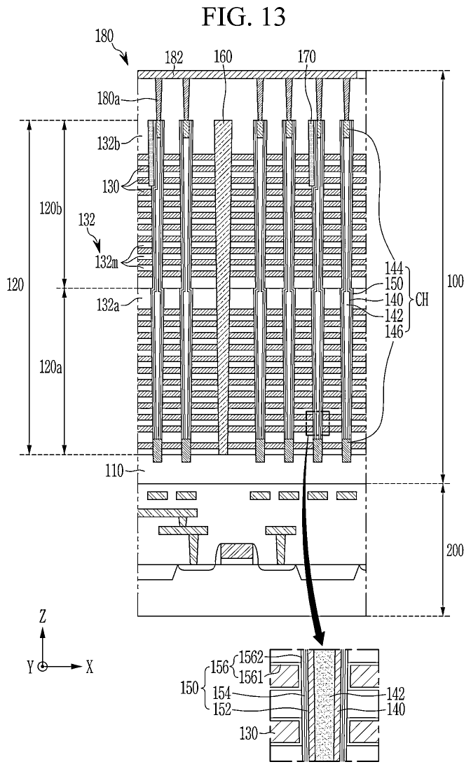

Hereinafter, a semiconductor device and a manufacturing method of the same according to at least one embodiment will be described in more detail with reference to FIGS. 13 to 18. To the extent that an element is not described in detail below, it may be understood that the element is at least substantially similar (and/or the same as) to a corresponding element that has been described elsewhere within the present disclosure. A portion which is not described in the above will be described in detail.

FIG. 13 is a cross-sectional view illustrating a semiconductor device according to at least one embodiment. In FIG. 13, a portion corresponding to a left portion of FIG. 1 is illustrated.

Referring to FIG. 13, in at least one embodiment, a partial portion of a blocking layer 156 (e.g., a first blocking layer 1561) including an insulating material may be at outside of a gate electrode 130. In at least one embodiment, the blocking layer 156 may include the first blocking layer 1561 including a portion extending horizontally along the gate electrode 130, and a second blocking layer 1562 extending vertically between the first blocking layer 1561 and a charge storage layer 154.

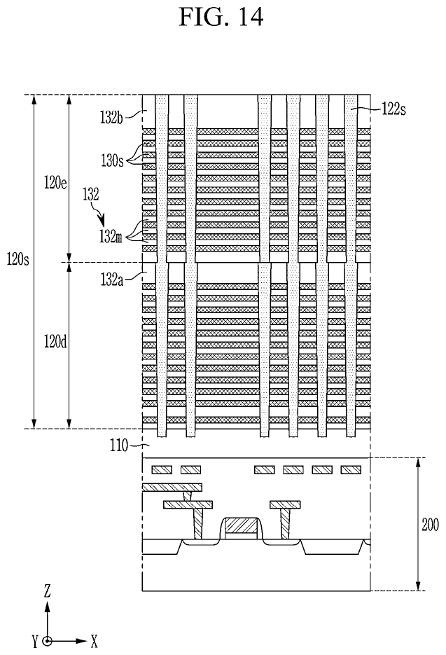

FIG. 14 to FIG. 18 are cross-sectional views illustrating a manufacturing method of a semiconductor device according to at least one embodiment. In FIG. 14 to FIG. 18, a portion corresponding to a left portion of FIG. 1 is illustrated. Hereinafter, a manufacturing method of a semiconductor device 10 will be described mainly based on a gate stacking structure 120, a channel structure CH, a separation structure 160, and a separation pattern 170 in a cell region 100.

As illustrated in FIG. 14, a second substrate 110 and a stacking structure 120s may be formed on a circuit region 200, and a channel sacrificial layer 122s and a separation structure 160 extending to penetrate the stacking structure 120s may be formed.

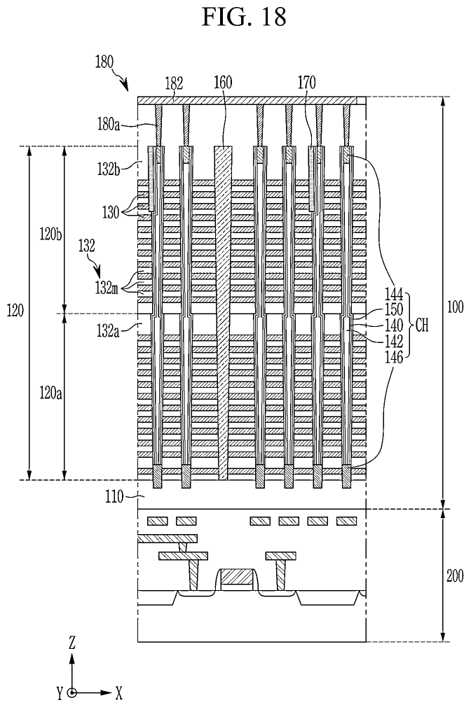

The stacking structure 120s may be formed by alternatively stacking interlayer insulation layers 132m and sacrificial insulation layers 130s on the second substrate 110 to form the stacking structure 120s. Subsequently, a preliminary penetrating portion (e.g., that penetrates the stacking structure 120s) may be formed at a portion where a channel structure CH (refer to FIG. 18) will be formed, and the preliminary penetrating portion may be filled with a sacrificial material to form the channel sacrificial layer 122s.

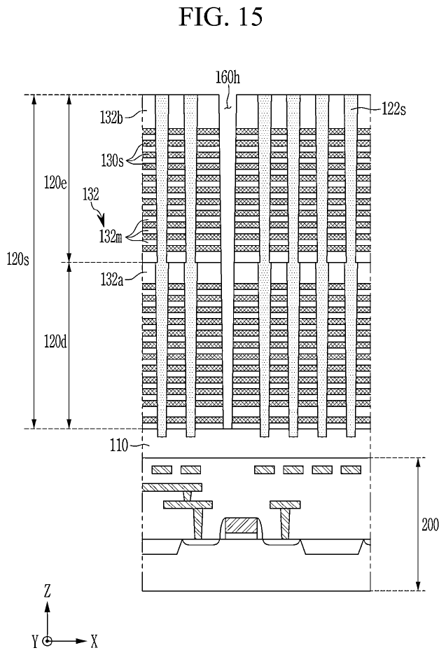

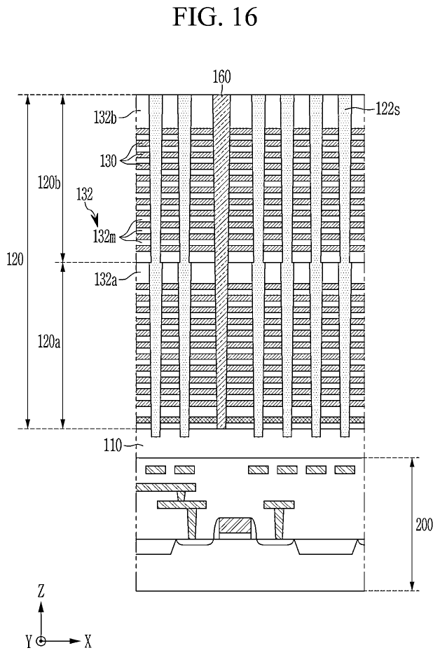

Subsequently, as illustrated in FIG. 15, an opening 160h for a separation structure that penetrates the stacking structure 120s may be formed in an area corresponding to a separation structure 160 (refer to FIG. 16). In at least one embodiment, the opening 160h for the separation structure may be formed by an etching process (e.g., a plasma etching process or the like).

Subsequently, as illustrated in FIG. 16, the sacrificial insulation layer 130s (refer to FIG. 15) may be replaced with a gate electrode 130, and the separation structure 160 may be formed.

More particularly, the sacrificial insulation layer 130s may be selectively removed by an etching process (e.g., a wet etching process) through the opening 160h (refer to FIG. 15) for the separation structure. The gate electrode 130 may be formed by filling a portion from which the sacrificial insulation layer 130s was removed with a conductive material. As a result, an area where the sacrificial insulation layer 130s was positioned may be replaced with the gate electrode 130. In these instances, a process of forming a partial portion of a blocking layer 156 (for example, a first blocking layer 1561) may be further performed before a process of filing the conductive material constituting the gate electrode 130. The semiconductor device manufactured by the above may have a structure as illustrated in FIG. 13. In some embodiments, the process for forming the partial portion of the blocking layer 156 (for example, the first blocking layer 1561) might not be performed. Then, the semiconductor device may have a structure as illustrated in an enlarged portion of FIG. 2.

The opening 160h for the separation structure may be filled with an insulating material or the like to form the separation structure 160.

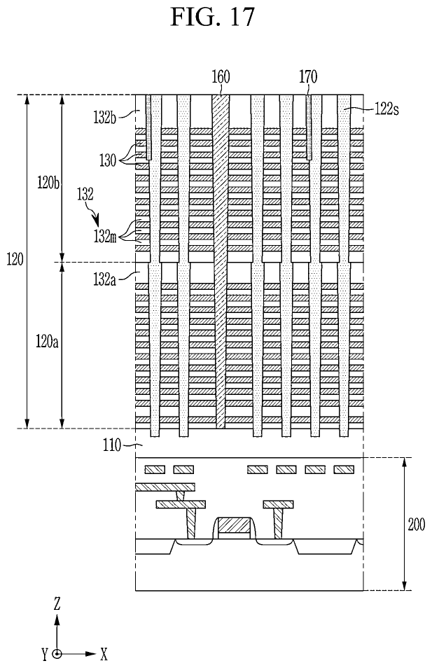

Subsequently, as illustrated in FIG. 17, a separation pattern 170 may be formed at a partial portion of the gate stacking structure 120. The separation pattern 170 may be formed by forming an opening for a separation pattern through an etching process using a mask layer and filling at least a partial portion of the opening for the separation pattern with an insulating material. For example, the separation pattern 170 that penetrates a selection gate electrode 130g (refer to FIG. 2) may be formed by forming the opening for the separation pattern that penetrates the selection gate electrode 130g.

The opening for the separation pattern may be formed by an etching process (e.g., a dry etching process or the like). The process for filling the opening for the separation pattern may be performed by, e.g., a deposition process or the like.

In at least one embodiment, when forming the opening for the separation pattern, partial portions of the channel sacrificial layers 122s at both sides of the opening for the separation pattern may be removed together. When forming the opening for the separation pattern, a surface exposed at the portion from which the channel sacrificial layer 122s is removed may constitute an adjacent surface S2 (refer to FIG. 4A to FIG. 4C).

The channel sacrificial layer 122s, among the plurality of channel sacrificial layers 122s, that is adjacent to or in contact with the separation pattern 170 may be replaced with an adjacent channel structure CH2 (refer to FIG. 4A to FIG. 4C) in a subsequent process. The channel sacrificial layer 122s, among the plurality of channel sacrificial layers 122s, that is spaced apart from the separation pattern 170 may be replaced with a separation channel structure CH1 (refer to FIG. 4A to FIG. 4C) in a subsequent process.

Subsequently, as illustrated in FIG. 18, a channel structure CH and a second wiring portion 180 may be formed.

More particularly, the channel sacrificial layer 122s (refer to FIG. 17) may be removed to form a penetrating portion, and the channel structure CH may be formed in the penetrating portion. Here, the description referring to FIG. 9 may be applied to the forming of the penetrating portion by removing the channel sacrificial layer 122s, and the description referring to FIG. 11 may be applied to the forming of the channel structure CH. A second wiring portion 180 (including a bit line 182 connected to the channel structure CH) and/or the like may be further formed.

According to at least one embodiment, after forming the separation pattern 170, the channel structure CH is formed. Therefore, in the first portion A1 of the adjacent channel structure CH2 adjacent to the separation pattern 170, the gate dielectric layer 150 and the channel layer 140 may be formed continuously without a cut portion or a cut surface. Accordingly, the adjacent channel structure CH2 may stably act as a memory cell string and a size of the semiconductor device 10 may be reduced. As a result, performance and productivity of the semiconductor device 10 may be improved.

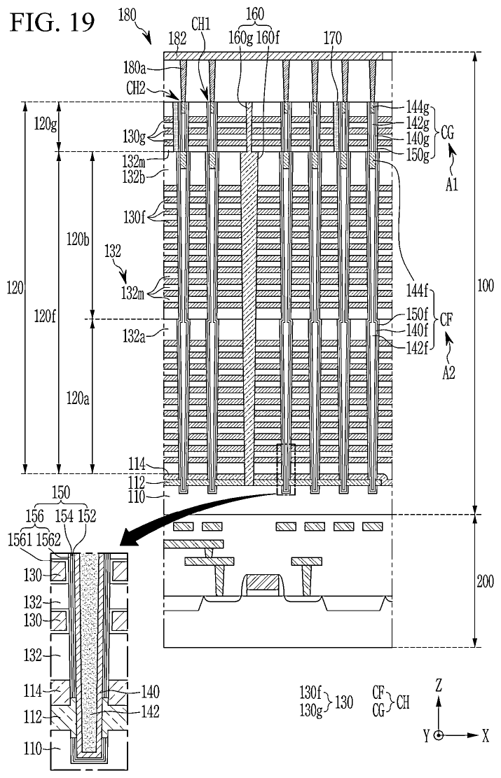

Hereinafter, a semiconductor device and a manufacturing method of the same according to at least one embodiment will be described in more detail with reference to FIGS. 19 to 25. To the extent that an element is not described in detail below, it may be understood that the element is at least substantially similar to (and/or the same as) a corresponding element that has been described elsewhere within the present disclosure. A portion which is not described in the above will be described in detail.

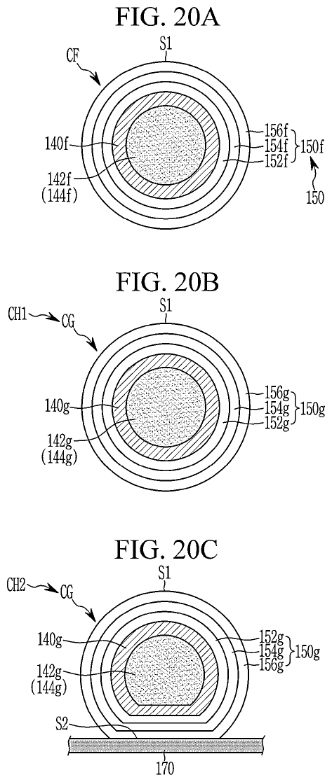

FIG. 19 is a cross-sectional view schematically illustrating a semiconductor device according to at least one embodiment. FIG. 20A to FIG. 20C are plan views of channel structures included in the semiconductor device illustrated in FIG. 19.

In FIG. 19, a portion corresponding to a left portion of FIG. 1 is illustrated. For simple illustration and a clear understanding, FIG. 19 schematically illustrates an example of at least one embodiment including a selection gate dielectric layer 150g, a selection channel layer 140g, and a selection channel pad 144g of a selection channel structure CG. In the disclosure, the term of “base” included in a base gate dielectric layer 150f, a base channel layer 140f, and a base channel pad 144f, or the term of “selection” included in the selection gate dielectric layer 150g, the selection channel layer 140g, and the selection channel pad 144g may be used to distinguish them. Accordingly, the embodiments are not limited thereto.

FIG. 20A illustrates a base channel structure CF. FIG. 20B illustrates a selection channel structure CG of a separation channel structure CH1. FIG. 20C illustrates a selection channel structure CG of an adjacent channel structure CH2.

Referring to FIG. 19, FIG. 20A to FIG. 20C, in at least one embodiment, a separation pattern 170 may be adjacent to or in contact with a part of the plurality of channel structures CH. For example, the plurality of channel structures CH may include a separation channel structure CH1 spaced apart from the separation pattern 170 and an adjacent channel structure CH2 adjacent to or in contact with the separation pattern 170.

In FIG. 19 and the description, an example where an electrical connection structure between the channel structure CH and the horizontal conductive layers 112 and 114 and/or the second substrate 110 is different from an electrical connection in the above embodiments is illustrated and described. The embodiments are not limited thereto, and the electrical connection structure between the channel structure CH and the second substrate 110 illustrated in FIG. 2 may be applied to the embodiment illustrated in FIG. 19. As such, the electrical connection structure between the channel structure CH and the second substrate 110 may be variously modified.

For example, in at least one embodiment, the gate stacking structure 120 may include a base stacking structure 120f and a selection stacking structure 120g on the base stacking structure 120f. The base stacking structure 120f may include cell insulation layers 132 and base gate electrodes 130f alternately stacked to each other, and the selection stacking structure 120g may include cell insulation layers 132 and a selection gate electrode 130g alternately stacked to each other. In these instances, the selection gate electrode 130g may include a string selection gate electrode that selects a string, and the separation pattern 170 may be a string separation pattern that separates the string. In some embodiments, the selection gate electrode 130g may further include a gate electrode other than the string selection gate electrode that selects the string.

In at least one embodiment, each channel structure CH may include a base channel structure CF extending to penetrate the base stacking structure 120f, and a selection channel structure CG being on the base channel structure CF and extending to penetrate the selection stacking structure 120g. For example, the separation channel structure CH1 may include the base channel structure CF and the selection channel structure CG, and the adjacent channel structure CH2 may include the base channel structure CF and the selection channel structure CG.

The base channel structure CF may include a base channel layer 140f, and a base gate dielectric layer 150f on the base channel layer 140f between the base gate electrode 130f and the base channel layer 140f. The base channel structure CF may further include a base core insulation layer 142f at an inside of the base channel layer 140f. However, the example embodiments are not limited thereto. For example, in some embodiments, the base core insulation layer 142f might not be provided. The base channel structure CF may include a base channel pad 144f electrically connected to a selection channel layer 140g of the selection channel structure CG. In the drawing, an example where the base channel structure CF does not include a semiconductor pattern 146 (refer to FIG. 2) adjacent to the second substrate 110 is illustrated. However, the embodiments are not limited thereto.

The base gate dielectric layer 150f between the base gate electrode 130f and the base channel layer 140f may include a base tunneling layer 152f, a base charge storage layer 154f, and a base blocking layer 156f sequentially on the base channel layer 140f.

An outer surface of the base channel structure CF may include or consist of a separation surface S1, and the base gate dielectric layer 150f and the base channel layer 140f may be entirely and continuously formed on the separation surface S1. The base channel structure CF of the adjacent channel structure CH2 and the base channel structure CF of the separation channel structure CH1 may have the substantially same (and/or substantially similar) structure, shape, or the like. Unless otherwise described, the description of the separation channel structure CH1 or the second portion A2 of the adjacent channel structure CH2 in the above embodiments and modified embodiments may be applied to the base channel structure CF.

The selection channel structure CG may include a selection channel layer 140g and a selection gate dielectric layer 150g on the selection channel layer 140g between the selection gate electrode 130g and the selection channel layer 140g. The selection channel structure CG may further include a selection core insulation layer 142g at an inside of the selection channel layer 140g. However, the embodiments are not limited thereto. For example, in some embodiments, the selection core insulation layer 142g might not be provided. The selection channel structure CG may include a selection channel pad 144g electrically connected to the selection channel layer 140g of the selection channel structure CG.

The selection channel layer 140g of the selection channel structure CG may be electrically connected to the base channel pad 144f and/or the base channel layer 140f of the base channel structure CF. The selection gate dielectric layer 150g between the selection gate electrode 130g and the selection channel layer 140g may include a selection tunneling layer 152g, a selection charge storage layer 154g, and a selection blocking layer 156g sequentially on the selection channel layer 140g.

The selection channel structure CG of the adjacent channel structure CH2 and the selection channel structure CG of the separation channel structure CH1 may have different planar shapes. In the adjacent channel structure CH2, an outer surface of the adjacent channel structure CH2 may include a separation surface S1 and an adjacent surface S2. In the adjacent channel structure CH2, the selection gate dielectric layer 150g may be entirely and continuously formed on the separation surface S1 and the adjacent surface S2, and the selection channel layer 140g may be entirely and continuously formed on the separation surface S1 and the adjacent surface S2.

In the separation channel structure CH1, an outer surface of the separation channel structure CH1 may include a separation surface S1. In the separation channel structure CH1, the selection gate dielectric layer 150g and the selection channel layer 140g may be entirely and continuously formed on the separation surface S1.

In the adjacent channel structure CH2, the selection channel structure CG may correspond to the first portion A1 of the adjacent channel structure CH2, and the base channel structure CF may correspond to the second portion A2 of the adjacent channel structure CH2. Unless otherwise described the description of the first portion A1 of the adjacent channel structure CH2 in the above embodiments and modified embodiments may be applied to the selection channel structure CG of the adjacent channel structure CH2. Unless otherwise described, the description of the separation structure CH1 or the second portion A2 of the adjacent channel structure CH2 in the above embodiments and modified embodiments may be applied to the selection channel structure CG of the separation channel structure CH1.

In a plan view at a portion where a core insulation layer (the base core insulation layer 142f or the selection core insulation layer 142g) is positioned, a stacking order of the selection gate dielectric layer 150g, the selection channel layer 140g, and the selection core insulation layer 142g in the selection channel structure CG of the adjacent channel structure CH2 that is adjacent to the separation pattern 170 may be the same a stacking order of the base gate dielectric layer 150f, the base channel layer 140f, and the base core insulation layer 142f in the base channel structure CF of the adjacent channel structure CH2. For example, the gate dielectric layer 150g or 150f, the channel layer 140g or 140f, the core insulation layer 142g or 142f, the channel layer 140g or 140f, and the gate dielectric layer 150g or 150f may be sequentially disposed in one direction passing through a center.

In a plan view at a portion where a core insulation layer (the base core insulation layer 142f or the selection core insulation layer 142g) is positioned, a stacking order of the selection gate dielectric layer 150g, the selection channel layer 140g, and the selection core insulation layer 142g in the selection channel structure CG of the adjacent channel structure CH2 that is adjacent to the separation pattern 170 may be the same a stacking order of a gate dielectric layer (the base gate dielectric layer 150f or the selection gate dielectric layer 150g), a channel layer (the base channel layer 140f or the selection channel layer 140g), and a core insulation layer (the base core insulation layer 142f or the selection core insulation layer 142g) in the separation channel structure CH1. For example, the gate dielectric layer 150g or 150f, the channel layer 140g or 140f, the core insulation layer 142g or 142f, the channel layer 140g or 140f, and the gate dielectric layer 150g or 150f may be sequentially disposed in one direction passing through the center.

In some embodiment, in a plan view at a portion where a channel pad (the base channel pad 144f or the selection channel pad 144g) is positioned, a stacking order of the selection gate dielectric layer 150g, the selection channel layer 140g, and the selection channel pad 144g in the selection channel structure CG of the adjacent channel structure CH2 that is adjacent to the separation pattern 170 may be substantially the same as (and/or substantially similar to) a stacking order of the base gate dielectric layer 150f, the base channel layer 140f, and the base channel pad 144f in the base channel structure CF of the adjacent channel structure CH2. In some embodiment, in a plan view at a portion where the channel pad (the base channel pad 144f or the selection channel pad 144g) is positioned, a stacking order of the selection gate dielectric layer 150g, the selection channel layer 140g, and the selection channel pad 144g in the selection channel structure CG of the adjacent channel structure CH2 that is adjacent to the separation pattern 170 may be the same a stacking order of the gate dielectric layer (the base gate dielectric layer 150f or the selection gate dielectric layer 150g), the channel layer (the base channel layer 140f or the selection channel layer 140g), and the channel pad (the base core channel pad 144f or the selection channel pad 144g) in the separation channel structure CH1.

In at least one embodiment, the separation structure 160 may include a base separation structure 160f penetrating the base stacking structure 120f, and a selection separation structure 160g penetrating the selection stacking structure 120g. The base separation structure 160f may have an inclined side such that a width of the base separation structure 160f gradually decreases toward the second substrate 110. The selection separation structure 160g may have a width less than the base separation structure 160f, and have an inclined side such that a width of the selection separation structure 160g gradually decreases toward the second substrate 110. A step portion or a bent portion may be between the base separation structure 160f and the selection separation structure 160g. However, the embodiments are not limited thereto. A side surface of the separation structure 160 might not have the step potion or the bent portion. Various other modifications are possible.

In at least one embodiment, horizontal conductive layers 112 and 114 may be provided between the second substrate 110 and the gate stacking structure 120 in a cell array region 102. The horizontal conductive layers 112 and 114 may electrically connect (e.g., directly connect) the channel structure CH and the second substrate 110. The horizontal conductive layers 112 and 114 may include a first horizontal conductive layer 112 and/or a second horizontal conductive layer 114 sequentially on the second substrate 110. The first horizontal conductive layer 112 may act as a partial portion of a common source line of the semiconductor device. For example, the first horizontal conductive layer 112 may act as the common source line together with the second substrate 110.

In at least one embodiment, the first and the second horizontal conductive layers 112 and 114 may include a semiconductor material (e.g., polycrystalline silicon). For example, the first horizontal conductive layer 112 may include a polycrystalline silicon layer including a dopant. The embodiments are not limited thereto. The second horizontal conductive layer 114 may include a material (e.g., an insulating material) different from a material of the first horizontal conductive layer 112, or the second horizontal conductive layer 114 might not be provided.

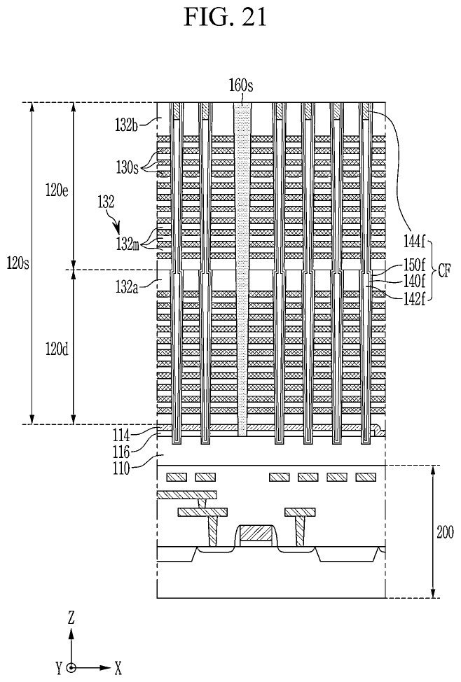

FIG. 21 to FIG. 25 are cross-sectional views illustrating a manufacturing method of a semiconductor device according to at least one embodiment. In FIG. 21 to FIG. 25, a portion corresponding to a left portion of FIG. 1 is illustrated. Hereinafter, a manufacturing method of a semiconductor device will be described mainly based on a gate stacking structure 120, a channel structure CH, a separation structure 160, and a separation pattern 170 in a cell region 100. To the extent that an element is not described in detail below, it may be understood that the element is at least substantially similar (and/or the same as) to a corresponding element that has been described elsewhere within the present disclosure. A portion which is not described in the above will be described in detail.

As illustrated in FIG. 21, a second substrate 110 and a stacking structure 120s may be formed on a circuit region 200. A base channel structure CF and a separation sacrificial layer 160s extending to penetrate the stacking structure 120s may be formed.

First, the second substrate 110 may be formed on the circuit region 200, and a horizontal insulation layer 116 and a second horizontal conductive layer 114 may be formed on the second substrate 110. Interlayer insulation layers 132m and sacrificial insulation layers 130s may be alternately stacked on the second horizontal conductive layer 114 to form the stacking structure 120s.

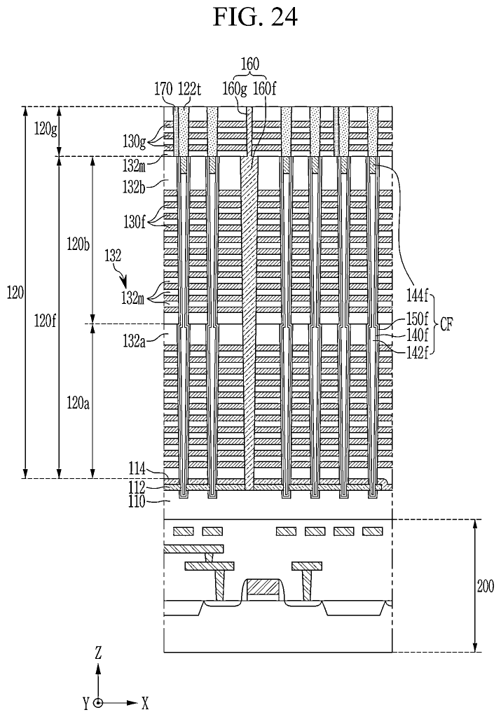

At least a partial portion of the horizontal insulation layer 116 may be a layer that will be replaced with a first horizontal conductive layer 112 (refer to FIG. 24) through a subsequent process. The horizontal insulation layer 116 may include a material different from a material of the interlayer insulation layer 132m. For example, the horizontal insulation layer 116 may include at least one of silicon, silicon oxide, silicon carbide, or silicon nitride, and may include a material different from a material of the interlayer insulation layer 132m.

Subsequently, a penetrating portion that penetrates the stacking structure 120s may be formed at a portion where a base channel structure CF will be formed, and the base channel structure CF may be formed in the penetrating portion. For example, a base gate dielectric layer 150f, a base channel layer 140f, a base core insulation layer 142f, and a base channel pad 144f may be sequentially formed to fill the penetrating portion. In these instances, a first blocking layer 1561 (refer to FIG. 19) of the base gate dielectric layer 150f might not be formed. The first blocking layer 1561 may be formed later in a subsequent process. An opening for a separation structure that penetrate the stacking structure 120s may be formed in an area corresponding to at least a part of a separation structure 160 (refer to FIG. 24), and the opening for the separation structure may be filled with a sacrificial material to form the separation sacrificial structure 160s.

In at least one embodiment, the penetrating portion may be formed through an etching process (e.g., a plasma etching process), and the base channel structure CF may be formed through, e.g., a deposition process.

The opening for the separation structure that penetrates the stacking structure 120s may be formed at a portion where a base separation structure 160f (refer to FIG. 24) will be formed, and the opening for the separation structure may be filled with a sacrificial material to form the separation sacrificial layer 160s. In at least one embodiment, the opening for the separation structure may be formed by an etching process (e.g., a plasma etching process or the like), and the opening for the separation structure may be filled by, e.g., a deposition process or the like. The separation sacrificial layer 160s may include at least one of polycrystalline silicon, tungsten, titanium nitride, or carbon.

A formation order of the base channel structure CF and the separation sacrificial structure 160s may be variously modified. For example, the separation sacrificial structure 160s may be formed after forming the base channel structure CF, or the base channel structure CF may be formed after forming the separation sacrificial structure 160s. In some embodiments, a part of the process of forming the penetrating portion for the channel structure and a part of the process of forming the opening for the separation structure may be performed together. In some embodiments, a part of the process of filling the penetrating portion for the channel structure and a part of the process of filling the opening for the separation structure may be performed together.

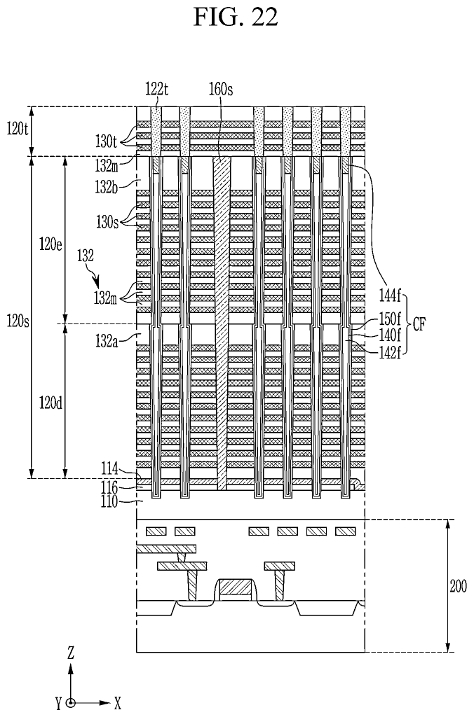

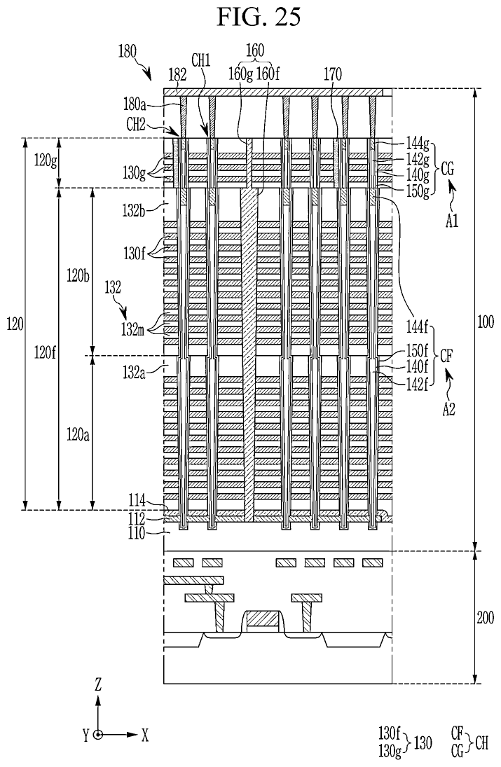

Subsequently, as illustrated in FIG. 22, cell insulation layers 132 and a selection sacrificial insulation layer 130t may be sequentially formed on the stacking structure 120s to form a selection stacking structure 120t, and a selection channel sacrificial layer 122t that extends to penetrate the selection stacking structure 120t may be formed. The selection channel sacrificial layer 122t may be positioned at a position corresponding to a channel structure CH (refer to FIG. 25). Here, the selection channel sacrificial layer 122t may be referred to as a preliminary channel structure.

Here, the selection sacrificial insulation layer 130t may be a layer that will be replaced with a selection gate electrode 130g (refer to FIG. 24) through a subsequent process, and the selection sacrificial insulation layer 130t may be formed to correspond to a portion where the selection gate electrode 130g will be formed.

The selection sacrificial insulation layer 130t may include a material different from a material of the cell insulation layer 132. For example, the cell insulation layer 132 may include silicon oxide, silicon nitride, silicon oxynitride, a low dielectric constant material, a high dielectric constant material, and/or the like. The selection sacrificial insulation layer 130t may include at least one of silicon, silicon oxide, silicon carbide, or silicon nitride different from a material of the interlayer insulation layer 132m.

Subsequently, a penetrating portion that penetrates the selection stacking structure 120t may be formed at a portion where a selection channel structure CG (refer to FIG. 25) is formed, and the penetrating portion may be filled with a sacrificial material to form the selection channel sacrificial layer 122t.

The selection channel sacrificial layer 122t may include a material different from a material of the cell insulation layer 132 and a material of the selection sacrificial insulation layer 130t. The selection channel sacrificial layer 122t may be a material having etch selectivity different from etch selectivity of the cell insulation layer 132 and etch selectivity of the selection sacrificial insulation layer 130t. Accordingly, the selection channel sacrificial layer 122t may selectively etched while the cell insulation layer 132 and the selection sacrificial insulation layer 130t remain. For example, the selection sacrificial insulation layer 130t may include at least one of silicon, silicon oxide, silicon carbide, or silicon nitride different from a material of the cell insulation layer 132 and a material of the selection sacrificial insulation layer 130t.

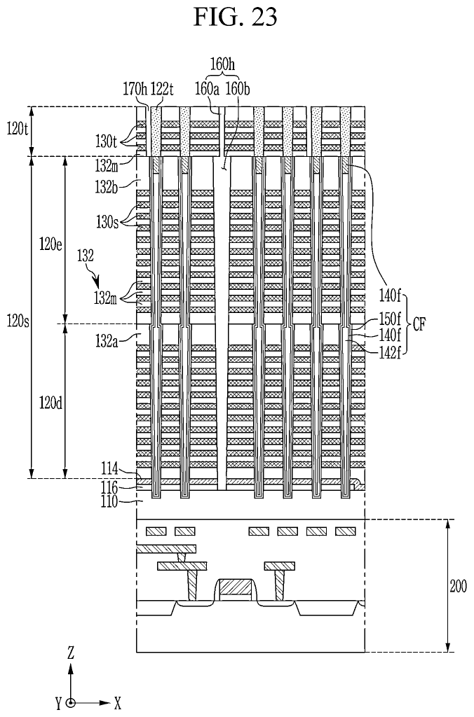

Subsequently, as illustrated in FIG. 23, an opening 170h for a separation pattern that penetrates the selection stacking structure 120t, and an opening 160h for a separation structure that penetrates the stacking structure 120s and the selection stacking structure 120t may be formed.

For example, the opening 170h for the separation pattern that penetrates the selection stacking structure 120t, and a part (more particularly, a first opening portion 160a) of the opening 160h for the separation structure that penetrates the selection stacking structure 120t may be formed. The separation sacrificial layer 160s (refer to in FIG. 22) may be removed by using the first opening portion 160a to form a second opening portion 160b that penetrates the stacking structure 120s. The first opening portion 160a and the second opening portion 160b may constitute the opening 160h for the separation structure. However, the embodiments are not limited thereto, and the processes of the opening 170h for the separation pattern, the first opening portion 160a, and the second opening portion 160b may be variously modified.

The opening 170h for the separation pattern, the first opening portion 160a, and/or the second opening portion 160b may be formed by an etching process (e.g., a dry etching process).

Subsequently, as illustrated in FIG. 24, the sacrificial insulation layer 130s (refer to FIG. 23) and the selection sacrificial insulation layer 130t (refer to FIG. 23) may be replaced with the gate electrodes 130, and a separation structure 160 and a separation pattern 170 may be formed.

More particularly, the sacrificial insulation layer 130s and the selection sacrificial insulation layer 130t may be selectively removed by an etching process (e.g., a wet etching process) through the opening 160h for the separation structure. The gate electrodes 130 may be formed by filling a portion from which sacrificial insulation layer 130s and the selection sacrificial insulation layer 130t were removed with a conductive material. For example, a region where the sacrificial insulation layer 130s may be replaced with a base gate electrode 130f, and a region where the selection sacrificial insulation layer 130t may be replaced with a selection gate electrode 130g. In this instance, before the process of filing the conductive material constituting the gate electrode 130, a process of forming a partial portion of the blocking layer 156 (for example, a first blocking layer 1561) may be further performed. However, the embodiments are not limited thereto. For example, in some embodiments, the process for forming the partial portion of the blocking layer 156 (for example, the first blocking layer 1561) may be omitted.

The opening 160h for the separation structure may be filled with an insulating material and/or the like to form the separation structure 160. The opening 170h for the separation pattern may be filled with an insulating material or the like to form the separation pattern 170.

For example, after forming the separation pattern 170 by filling the opening 170h for the separation pattern with the insulating material or the like, the gate electrode 130 may be formed using the opening 160h for the separation structure, and the opening 160h for the separation structure may be filled with the insulating material or the like to form the separation structure 160. Thereby, the gate electrode 130 is replaced after the separation pattern 170 is formed, thereby simplifying the process. However, the embodiments are not limited thereto, and an order of the replacement process of the gate electrode 130, the formation of the separation structure 160, and the formation of the separation pattern 170 may be variously modified.

In at least one embodiment, an example where the sacrificial insulation layer 130s and the selection sacrificial insulation layer 130t may be replaced with the base gate electrode 130f and the selection gate electrode 130g, respectively, in the same process is described. However, the embodiments are not limited thereto. Therefore, after the sacrificial insulation layer 130s is replaced with the base gate electrode 130f, the selection stacking structure 120t may be formed. Subsequently, the selection sacrificial insulation layer 130t may be replaced with the selection gate electrode 130g. Various other modifications are possible.

Subsequently, as illustrated in FIG. 25, the selection channel sacrificial layer 122t may be removed and a selection channel structure CG may be formed.

In at least one embodiment, a selection gate dielectric layer 150g, a selection channel layer 140g, and a selection core insulation layer 142g may be sequentially formed in a penetrating portion formed by removing the selection channel sacrificial layer 122t, and a selection channel pad 144g may be formed. The selection channel layer 140g may be electrically connected to the base channel layer 140f and/or the base channel pad 144f. The selection gate dielectric layer 150g, the selection channel layer 140g, and the selection core insulation layer 142g may be formed by, e.g., a deposition process or the like. Subsequently, a second wiring portion 180 including a bit line 182 connected to the channel structure CH and/or the like may be further formed.

According to the embodiment, the selection stacking structure 120g and the selection channel structure CG may be separately formed in a portion where the separation pattern 170 is formed. Thus, the forming process of the base stacking structure 120f and the base channel structure CF may be maintained. As a result, the semiconductor device 10 may be formed through an easy process.

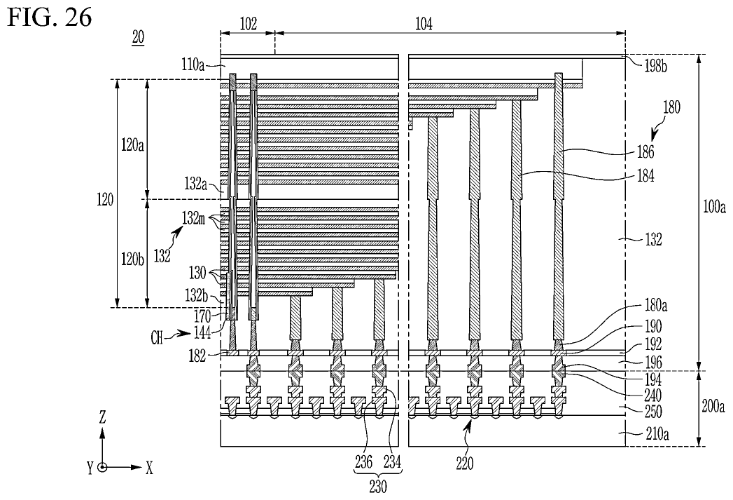

At least one embodiment will be described with reference to FIG. 26. To the extent that an element is not described in detail below, it may be understood that the element is at least similar to a corresponding element that has been described elsewhere within the present disclosure. A portion different from the above will be mainly described in detail.

FIG. 26 is a cross-sectional view schematically illustrating a semiconductor device 20 according to at least one embodiment.

Referring to FIG. 26, a semiconductor device 20 according to at least one embodiment may have a chip-to-chip (C2C) structure bonded by a wafer bonding type. That is, a lower chip including a circuit region 200a having a first substrate 210a may be manufactured, an upper chip including a cell region 100a having a second substrate 110a may be manufactured, and then a semiconductor device 20 may be manufactured by bonding the lower chip and the upper chip.

The circuit region 200a may include the first substrate 210a, a circuit element 220, a first wiring portion 230, and a first bonding structure 240 electrically connected to the first wiring portion 230 at a surface facing the cell region 100a. A region, other than the first bonding structure 240 at the surface facing the cell region 100a, may be covered by a first insulation layer 250.

The cell region 100a may include a second substrate 110a, a gate stacking structure 120, a channel structure CH, a second wiring portion 180, and a second bonding structure 194 electrically connected the second wiring portion 180 at a surface facing the circuit region 200a. A region other than the second bonding structure 194 may be covered by an insulation layer 196.

In at least one embodiment, the second substrate 110a may be a semiconductor substrate including a semiconductor material. The semiconductor material may be an elemental semiconductor (e.g., silicon or germanium) and/or a compound semiconductor (e.g., a Group III-V, II-VI, and/or IV-IV semiconductor). For example, the second substrate 110a may be a semiconductor substrate of a semiconductor material and/or may be a semiconductor substrate in which a semiconductor layer is on a base substrate. For example, the second substrate 110a may include single-crystalline or polycrystalline silicon, germanium, silicon-germanium, silicon-on-insulator, germanium-on-insulator, or the like. In some embodiments, the second substrate 110a may be a supporting member including an insulation layer or an insulating material. This is because a semiconductor substrate provided in the cell region 100a may be removed after the cell region 100a is bonded to the circuit region 200a and the supporting member including the insulation layer or the insulating material may be formed.

In at least one embodiment, the gate stacking structure 120 may be sequentially stacked on a lower portion of the second substrate 110a in the drawing, and may have a structure in which the gate stacking structure 120 illustrated in FIG. 2 is disposed in a vertically inverted manner. The channel structure CH penetrating the gate stacking structure 120 may have a structure in which the channel structure CH illustrated in FIG. 2 is disposed in a vertically inverted manner. Accordingly, in a cross-sectional view, the channel structure CH may have an inclined side surface such that a width of the channel structure CH decreases from the circuit region 200a toward the second substrate 110a. The channel pad 144 and the second wiring portion 180 at upper portion of the gate stacking structure 120 may be adjacent to the circuit region 200a.

For example, the first bonding structure 240 and/or the second bonding structure 194 may include aluminum, copper, tungsten, or an alloy including the same. For example, the first and second bonding structures 240 and 194 may include copper such that the cell region 100a and the circuit region 200a may be bonded (e.g., directly bonded) to each other by copper-to-copper (or direct) bonding.

In FIG. 26, it is illustrated as an example that the gate stacking structure 120 includes a plurality of gate stacking structures 120a and 120b. In some embodiment, the gate stacking structure 120 may include one gate stacking structure or three or more gate stacking structures. Unless otherwise described, the description of the gate stacking structure 120 and the channel structure CH with reference to FIG. 1 to FIG. 25 may be applied. In FIG. 26, an example where an electrical connection structure between the channel structure CH and the second substrate 110a is illustrated as the same as an electrical connection structure between the channel structure CH and the second substrate 110a illustrated in FIG. 2. However, the embodiments are not limited thereto, and the electrical connection structure between the channel structure CH and the second substrate 110a may be variously modified.

The semiconductor device 20 according to at least one embodiment may include an input/output pad, and a through plug or an input/output connection wiring electrically connected to the input/output pad. The input/output connection wiring may be electrically connected to a part of the second bonding structure 194. For example, the input/output pad may be on an insulation layer 198b covering an outer surface of the second substrate 110a. In some embodiments, an additional input/output pad electrically connected to the circuit region 200a may be provided.

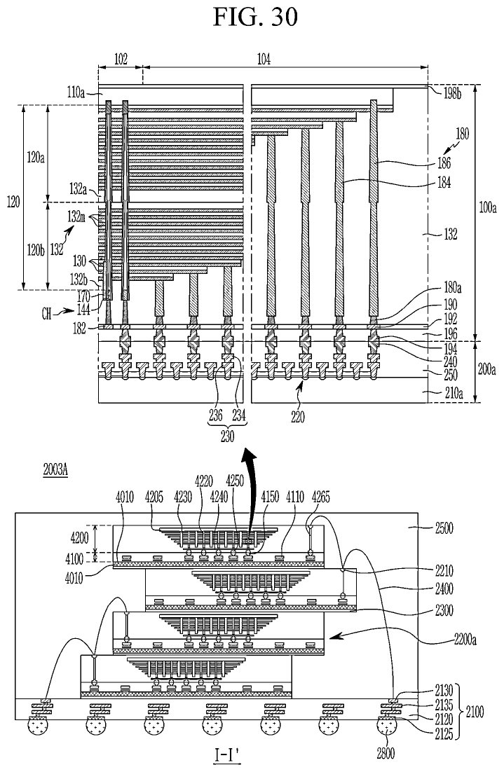

For example, the circuit region 200a and the cell region 100a may be portions corresponding to a first structure 1100F and a second structure 1100S of a semiconductor device 1100 included in an electronic system 1000 illustrated in FIG. 27, respectively. For example, the circuit region 200a and the cell region 100a may be regions including a first structure 4100 and a second structure 4200 of a semiconductor chip 2200a illustrated in FIG. 30, respectively.

An example of an electronic system including the semiconductor device will be described in detail below.

FIG. 27 is a view schematically illustrating an electronic system including a semiconductor device according to at least one embodiment.

Referring to FIG. 27, an electronic system 1000 according to at least one embodiment may include a semiconductor device 1100 and a controller 1200 electrically connected to the semiconductor device 1100. The electronic system 1000 may be a storage device including one or a plurality of semiconductor devices 1100 and/or an electronic device including the storage device. For example, the electronic system 1000 may be a solid-state drive (SSD) device, a universal serial bus (USB), a computing system, a medical device, a communication device including one or a plurality of semiconductor devices 1100, and/or the like.

The semiconductor device 1100 may be a non-volatile memory device, and for example, may be a NAND flash memory device described with reference to FIG. 1 to FIG. 26. The semiconductor device 1100 may include a first structure 1100F and a second structure 1100S on the first structure 1100F. In some embodiments, the first structure 1100F may be next to the second structure 1100S. The first structure 1100F and the second structure 1100S may correspond to, e.g., the circuit region 200 and the cell region 100 of FIG. 1 to FIG. 26, respectively. For example, the first structure 1100F may be a peripheral circuit structure including a decoder circuit 1110, a page buffer 1120, and a logic circuit 1130; and the second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to at least one embodiment.

In at least one embodiment, the lower transistors LT1 and LT2 may include a ground selection transistor, and the upper transistors UT1 and UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 extending to the second structure 1100S within the first structure 1100F. The bit line BL may be electrically connected to the page buffer 1120 through a second connection wiring 1125 extending to the second structure 1100S within the first structure 1100F.

In the first structure 1100F, the decoder circuit 1110 and the page buffer 1120 may be configured to execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending to the second structure 1100S within the first structure 1100F.

The controller 1200 may include a processor 1210, a NAND controller 1220, and a host interface 1230. According to at least one embodiment, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate, e.g., according to firmware, and may be configured to access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

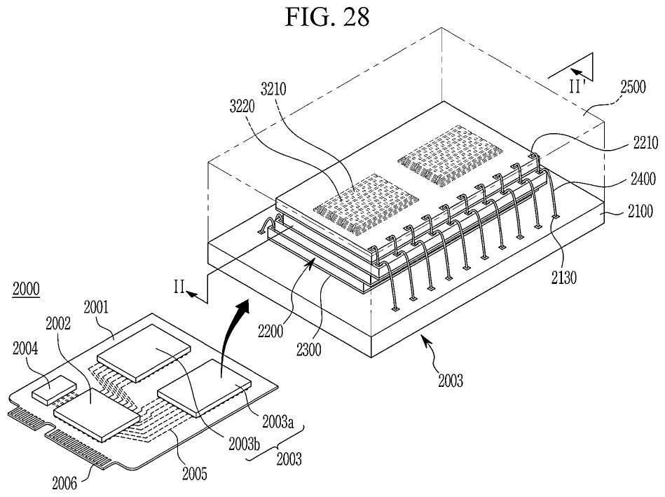

FIG. 28 is a perspective view schematically illustrating an electronic system including a semiconductor device according to at least one embodiment.

Referring to FIG. 28, an electronic system 2000 according to at least one embodiment may include a main substrate 2001, a controller 2002 on the main substrate 2001, one or more semiconductor packages 2003, and a DRAM 2004. The semiconductor package 2003 and the DRAM 2004 may be connected to the controller 2002 through a wiring pattern 2005 at the main substrate 2001.

The main substrate 2001 may include a connector 2006 including a plurality of pins coupled to the external host. A number and an arrangement of the plurality of pins in the connector 2006 may vary depending on a communication interface between the electronic system 2000 and the external host. In at least one embodiment, the electronic system 2000 may communicate with the external host according to any one of interfaces such as a universal serial bus (USB), a peripheral component interconnect express (PCI-Express), a serial advanced technology attachment (SATA), and an M-Phy for a universal flash storage (UFS). In at least one embodiment, the electronic system 2000 may operate by power supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chip 2200 on the package substrate 2100, an adhesive layer 2300 at a lower surface of each semiconductor chip 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 27. Each semiconductor chip 2200 may include a gate stacking structure 3210 and a channel structure 3220. The semiconductor chip 2200 may include the semiconductor device described with reference to FIG. 1 to FIG. 26.

In at least one embodiment, the connection structure 2400 may be a bonding wire electrically connecting the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to a package upper pad 2130 of the package substrate 2100. According to at least one embodiment, in each of the first and second semiconductor packages 2003a and 2003b, the semiconductor chips 2200 may be electrically connected to each other by a connection structure including a through silicon via (TSV) instead of the connection structure 2400 using the bonding wire type.

In at least one embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring at the interposer substrate.

FIG. 29 and FIG. 30 are cross-sectional views schematically illustrating semiconductor packages according to some embodiments, respectively. FIG. 29 and FIG. 30 respectively describe embodiments of the semiconductor package 2003 of FIG. 28, and conceptually illustrate a region obtained by cutting the semiconductor package 2003 of FIG. 28 along a line I-I′.

Referring to FIG. 29, in the semiconductor package 2003, the package substrate 2100 may be a printed circuit board. The package substrate 2100 may include a package substrate body portion 2120, a package upper pad 2130 at an upper surface of the package substrate body portion 2120, a package lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the connection structure 2400. The package lower pad 2125 may be connected to a wiring pattern 2005 of the main substrate 2001 of the electronic system 2000, as illustrated in FIG. 28, through a conductive connection portion 2800.

The semiconductor chip 2200 may include a semiconductor substrate 3010, and a first structure 3100 and a second structure 3200 sequentially stacked on the semiconductor substrate 3010. The first structure 3100 may include a peripheral circuit region including a peripheral wiring 3110. The second structure 3200 may include a common source line 3205, a gate stacking structure 3210 on the common source line 3205, a channel structure 3220 and a separation structure 3230 penetrating the gate stacking structure 3210, a bit line 3240 electrically connected to the channel structure 3220, and a gate connection wiring electrically connected to a word line WL (refer to FIG. 27) of the gate stacking structure 3210.

In a semiconductor chip 2200 or a semiconductor device according to at least one embodiment, performance and productivity of the semiconductor chip 2200 or the semiconductor device may be enhanced by including a gate dielectric layer and/or a channel layer continuously formed in an adjacent channel structure adjacent to a separation pattern.

Each of the semiconductor chips 2200 may include a through wiring 3245 that is electrically connected to a peripheral wiring 3110 of the first structure 3100 and extends into the second structure 3200. The through wiring 3245 may penetrate the gate stacking structure 3210, and may be further provided at an outside of the gate stacking structure 3210. Each semiconductor chip 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In at least one embodiment, in the semiconductor package 2003, a plurality of semiconductor chips 2200 may be electrically connected to each other by a connection structure 2400 having a bonding wire type. In some embodiments, the plurality of semiconductor chips 2200 or a plurality of portions constituting the plurality of semiconductor chips 2200 may be electrically connected by a connection structure including a through silicon via (TSV).

Referring to FIG. 30, in a semiconductor package 2003A, each semiconductor chip 2200a may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second bonding structure 4250 electrically connected to the channel structure 4220 and a word line WL (refer to FIG. 27) of the gate stacking structure 4210. For example, the second bonding structure 4250 may be electrically connected to the channel structure 4220 and the word line WL through a bit line 4240 electrically connected to the channel structure 4220 and a gate connection wiring electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In a semiconductor chip 2200a or a semiconductor device according to at least one embodiment, performance and productivity of the semiconductor chip 2200 or the semiconductor device may be enhanced by including a gate dielectric layer and/or a channel layer continuously formed in an adjacent channel structure adjacent to a separation pattern.

Each of the semiconductor chips 2200a may further include an input/output pad 2210 and an input/output connection wiring 4265 at a lower portion of the input/output pad 2210. The input/output connection wiring 4265 may be electrically connected to a part of the second bonding structure 4250.

In at least one embodiment, in the semiconductor package 2003A, a plurality of semiconductor chips 2200a may be electrically connected to each other by the connection structure 2400 having a bonding wire type. In some embodiments, the plurality of semiconductor chips 2200a or a plurality of portions constituting the plurality of semiconductor chips 2200a may be electrically connected by a connection structure including a through silicon via (TSV).

While some examples have been described in connection with what is presently considered to be some practical embodiments, it is to be understood that the disclosure is not limited to the disclosed embodiments, and that that the disclosure is intended to cover various modifications and equivalent arrangements included within the spirit and scope of the appended claims.

What is claimed is:

1. A semiconductor device, comprising:
a gate stacking structure, the gate stacking structure including a plurality of interlayer insulation layers and a plurality of gate electrodes alternately stacked with each other on a substrate, the plurality of gate electrodes including a selection gate electrode;
a plurality of channel structures extending in a direction crossing the substrate such that the plurality of channel structures penetrate the gate stacking structure, each of the plurality of channel structures including a gate dielectric layer and a channel layer; and
at least one separation pattern separating the selection gate electrode at one surface of the gate stacking structure,
wherein the plurality of channel structures includes an adjacent channel structure adjacent to the at least one separation pattern,
the adjacent channel structure includes a first portion having an adjacent surface adjacent to the separation pattern and having a separation surface spaced apart from the separation pattern, and
at least one of the gate dielectric layer or the channel layer, in the first portion of the adjacent channel structure, is on the separation surface and the adjacent surface.

2. The semiconductor device of claim 1, wherein, in a plan view, the gate dielectric layer and the channel layer are continuously and entirely disposed in the first portion such that the gate dielectric and the channel layer do not have a cut surface.

3. The semiconductor device of claim 1, wherein
the adjacent channel structure further includes a second portion other than the first portion, and
in a cross-sectional view, the gate dielectric layer and the channel layer are continuously and entirely disposed in the first portion and the second portion such that the gate dielectric layer and the channel layer do not have a cut surface.

4. The semiconductor device of claim 1, wherein,
in the first portion, the gate dielectric layer includes a first dielectric portion on the separation surface, and a second dielectric portion connected to the first dielectric portion on the adjacent surface, and
in the first portion, the channel layer includes a first channel portion on the first dielectric portion on the separation surface, and a second channel portion connected to the first channel portion on the second dielectric portion on the adjacent surface.

5. The semiconductor device of claim 4, wherein at least one of the connected first dielectric and second dielectric portions have an asymmetric shape or the connected first channel and second channel portions have an asymmetric shape.

6. The semiconductor device of claim 4, wherein, in a plan view,
at least one of the first dielectric portion or the first channel portion has a partially annular shape, and
at least one of the second dielectric portion or the second channel portion has a shape different from the partially annular shape.

7. The semiconductor device of claim 4, wherein at least one of an area of the first dielectric portion is greater than an area of the second dielectric portion or an area of the first channel portion is greater than an area of the second channel portion.

8. The semiconductor device of claim 4, wherein
the adjacent channel structure further includes a second portion,
a dielectric portion of the gate dielectric layer in the second portion is connected to the first dielectric portion and the second dielectric portion of the gate dielectric layer in the first portion, and
a channel portion of the channel layer in the second portion is connected to the first channel portion and the second channel portion of the channel layer in the first portion.

9. The semiconductor device of claim 1, wherein the separation surface of the first portion has a rounded surface, and
the adjacent surface of the first portion has a planar surface, a rounded surface having a curvature less than a curvature of the separation surface, or a curvature having a curvature direction opposite to a curvature direction of the separation surface.

10. The semiconductor device of claim 1, wherein the first portion further includes at least one of a core insulation layer surrounded by the channel layer, or a channel pad on at least one of the channel layer or the core insulation layer, and
the at least one of the core insulation layer or the channel pad in the first portion is entirely spaced apart from the separation pattern.

11. The semiconductor device of claim 1, wherein the adjacent channel structure includes a second portion,
the adjacent channel structure further includes a core insulation layer surrounded by the channel layer, and
in a plan view, a stacking order of the gate dielectric layer, the channel layer, and the core insulation layer in the first portion is the same as a stacking order of the gate dielectric layer, the channel layer, and the core insulation layer in the second portion.

12. The semiconductor device of claim 1, wherein the plurality of channel structures further include at least one separation channel structure spaced apart from the separation pattern, the at least one separation channel structure having a planar shape different from a planar shape of the first portion of the adjacent channel structure.

13. The semiconductor device of claim 12, wherein the adjacent channel structure and the separation channel structure each further include at least one of a core insulation layer surrounded by the channel layer or a channel pad on at least one of the channel layer or the core insulation layer, and
in a plan view, a stacking order of the gate dielectric layer, the channel layer, and the core insulation layer in the adjacent channel structure is the same as a stacking order of the gate dielectric layer, the channel layer, and the core insulation layer in the at least one separation channel structure, or a stacking order of the gate dielectric layer, the channel layer, and the channel pad in the adjacent channel structure is the same as a stacking order of the gate dielectric layer, the channel layer, and the channel pad in the at least one separation channel structure.

14. The semiconductor device of claim 1, wherein
the separation pattern includes an insulating separation pattern, or
the separation pattern includes a spacer layer and a conductive layer inside the spacer layer.

15. The semiconductor device of claim 1, wherein
the gate stacking structure includes a base stacking structure and a selection stacking structure on the base stacking structure, the selection stacking structure including a selection gate electrode,
the adjacent channel structure includes a base channel structure penetrating the base stacking structure and a selection channel structure penetrating the selection stacking structure, and
the separation pattern is adjacent to the selection channel structure of the adjacent channel structure such that the selection channel structure of the adjacent channel structure constitutes the first portion of the adjacent channel structure.

16. The semiconductor device of claim 15, wherein, in a plan view, in the selection channel structure of the adjacent channel structure, the gate dielectric layer and the channel layer are continuously and entirely disposed such that the gate dielectric layer and the channel layer do not have a cut surface.

17. An electronic system, comprising:
a main substrate;
a semiconductor device on the main substrate; and
a controller electrically connected to the semiconductor device on the main board,
wherein the semiconductor device includes
a gate stacking structure, the gate stacking structure including a plurality of interlayer insulation layers and a plurality of gate electrodes alternately stacked with each other on a substrate, the plurality of gate electrodes including a selection gate electrode;
a plurality of channel structures extending in a direction crossing the substrate such that the plurality of channel structures penetrate the gate stacking structure, each of the plurality of channel structures including a gate dielectric layer and a channel layer; and
at least one separation pattern separating the selection gate electrode at one surface of the gate stacking structure,
wherein the plurality of channel structures includes an adjacent channel structure adjacent to the at least one separation pattern,
the adjacent channel structure includes a first portion having an adjacent surface adjacent to the separation pattern and having a separation surface spaced apart from the separation pattern, and
at least one of the gate dielectric layer or the channel layer, in the first portion of the adjacent channel structure, is on the separation surface and the adjacent surface.

18. A manufacturing method of a semiconductor device, comprising:
forming a stacking structure;
forming a plurality of preliminary channel structures penetrating the stacking structure;
forming a separation pattern by forming an opening for the separation pattern to overlap at least one of the plurality of preliminary channel structures and filling at least a partial portion of the opening for the separation pattern with an insulating material; and
removing the plurality of preliminary channel structures and forming a plurality of channel structures.

19. The manufacturing method of claim 18, wherein
the plurality of channel structures include an adjacent channel structure, the adjacent channel structure including an adjacent surface adjacent to the separation pattern and a separation surface spaced apart from the separation pattern, and
the forming of the plurality of channel structures includes forming a gate dielectric layer and a channel layer on the adjacent surface adjacent to the separation pattern in the adjacent channel structure.

20. The manufacturing method of claim 19, wherein the forming of the plurality of channel structures includes forming a gate dielectric layer and a channel layer in the adjacent channel structure such that such that the gate dielectric and the channel layer do not have a cut surface in a plan view.
